(19) United States
(12) Patent Application Publication
(10) Pub. No.: US 2022/0252906 A1
(43) Pub. Date: Aug. 11, 2022

(54) COMPUTER-IMPLEMENTED METHOD FOR INDIVIDUALISING A SPECTACLE FRAME ELEMENT BY DETERMINING A PARAMETRIC SUBSTITUTION MODEL OF A SPECTACLE FRAME ELEMENT, AND DEVICE AND SYSTEMS USING SUCH A METHOD

(71) Applicant: Carl Zeiss Vision International GmbH, Aalen (DE)

(72) Inventors: Oliver Schwarz, Ellwangen (DE); Armin Eichert, Ellwangen (DE)

(21) Appl. No.: 17/721,630

(22) Filed: Apr. 15, 2022

Related U.S. Application Data
(63) Continuation-in-part of application No. PCT/EP2020/079293, filed on Oct. 16, 2020.

(30) Foreign Application Priority Data
Oct. 18, 2019 (EP) 19204207.5

(51) Int. Cl. G02C 13/00; G02C 5/14; G06F 30/10

(52) U.S. Cl. CPC G02C 13/005; G06F 30/10; G02C 5/14

(57) ABSTRACT

A spectacle frame element is individualized by adapting a parametric model of the spectacle frame element to the head of a spectacles-wearer. A parametric substitution model, having at least one parameter, for the parametric model of the spectacle frame element is determined by specifying a plurality of instances of the parametric model in the form of realizations of the parametric model using concrete parameter values, at least one basic instance and at least one parametric deformation map for the at least one basic instance are determined from the predefined instances, the at least one parametric deformation map mapping the at least one basic instance to instances of the parametric model, and the parametric substitution model being determined at least from the at least one basic instance and the at least one parametric map.

### CROSS REFERENCE TO RELATED APPLICATIONS

This application is a continuation-in-part application of international patent application PCT/EP2020/079293, filed Oct. 16, 2020, designating the United States and claiming priority from European patent application 19 204 207.5, filed Oct. 18, 2019, both of which are hereby incorporated by reference in their entireties.

### TECHNICAL FIELD

The disclosure relates to a computer-implemented method for individualizing a spectacle frame element by fitting a parametric model of a spectacle frame element to the head of a spectacles wearer by determining a parametric equivalent model having at least one parameter for a parametric model of a spectacle frame element. The disclosure moreover relates to an apparatus for individualizing and fitting a parametric model of a spectacle frame element to the head of a spectacles wearer, and to an apparatus for representing and/or compressing a given entity of a parametric model of a spectacle frame element. In addition, the disclosure relates to a computer program product having a computer program with program code for carrying out the method, and to a system having a device for producing an individualized spectacle frame element or for grinding spectacle lenses into an individualized spectacle frame element.

### BACKGROUND

By now, centration measurement equipment for spectacle frame elements have facilitated a fully automatic, computer-controlled centration measurement, the individualization of a spectacle frame element available as a parametric model, and the fitting of said spectacle frame element to the head of a spectacles wearer. To this end, a 3-D scanning method is used to measure parts of the head of the spectacles wearer, and the head model generated in the process is stored in the random access memory or the hard drive space of a computer unit. The extent and/or the alignment of the spectacle frame element or of parts thereof and distances and/or angles between its parts are preferably altered in such a way that, for the fit to the head model of the spectacles wearer, the spectacle frame element corresponds to the geometry of the head model.

The spectacle frame elements are usually available as parametric models, e.g., as CAD models, in a certain program-specific data format, e.g., as an STL, STEP, OBJ or PLY file, in the memory of the computer unit. Modeling programs, e.g., CAD programs such as “Creo,” “SolidWorks,” “Autodesk,” “FreeCAD,” or “OpenSCAD,” can be used to generate such models.

However, as a rule, these modeling programs do not contain the functionality of fitting a parametric model of a spectacle frame element to a head model. Instead, only entities of the parametric model of the spectacle frame element can be generated and stored. However, such entities are not suitable for the individualization and fitting of spectacle frame elements as these entities do not contain any parameters and therefore cannot be altered and fitted to the head model of the spectacles wearer.

Additionally, the parametric models generated on the basis of a modeling program are not suitable for use in a system that is independent of the modeling program, e.g., a fitting system for spectacle frame elements, for the following reasons:

Firstly, modeling programs as a rule do not offer the option of exporting and storing the parametric model underlying a spectacle frame element. This is because the representation formats for parametric models, as used by the modeling programs, are usually only designed for the internal representation and processing of the data within the respective modeling program—and not for the use in a system that is independent of the modeling program. Secondly, as a rule, the methods for representing and using the parametric models used within a modeling program are not publicly accessible, and so the parametric models cannot be used without additional information.

Therefore, for the purposes of individualizing and fitting spectacle frame elements, it is necessary to make parametric models available outside of the modeling program as well. To this end, use can be made of what is known as a reverse engineering method which for a given parametric model generates a parametric equivalent model that is independent of its modeling program. In this context, it is particularly important to automate the time-consuming process of generating alterable parametric equivalent models for a given base model to the greatest possible extent.

A method for determining a parametric substitutional model from a parametric model is known from WO 2019/051243 A1. This method comprises the following steps:
providing an entity of a CAD element model,
identifying one or more geometric features of the CAD model, for example holes, flanges, pipes, walls, tension or load regions, etc., and the modification thereof on the basis of rules and templates;
automatically creating a parametric equivalent model on the basis of the geometric features with geometric parameters such as, e.g., width, height, thickness, diameter, etc.;
calculating a modified entity of the CAD model on the basis of a selection of the geometric features and associated parameter values.

In this case, the automatic identification of one or more geometric features in the form of holes, flanges, pipes, walls, etc., and the modification thereof is implemented on the basis of rules and templates to be defined in advance. To this end, respective recognition routines have to be programmed for the individual specific features and geometric parameters have to be defined for the modification of the individual features. Since the specified method is not specialized in spectacle frame elements, the definition of the recognition routines and parameters for each feature of a spectacle frame element means a significant amount of outlay for the programmer. Additionally, since the parametric equivalent model is not defined in data-driven fashion but on the basis of rules and templates defined by the programmer, this measure can easily lead to unrealistic parametric equivalent models. Moreover, only individual geometric features of the model are detected and parameterized, and so it is only these that are alterable and not the entire object. Moreover, the calculated parametric model is available in the same data format as the base model, and so the use of the equivalent model depends on the modeling program.

For these reasons, the method is not suitable for individualizing and fitting complex models with many different geometric features, such as spectacle frame elements for example, in a fitting system.

The publication “CAD Model Creation from Dense Pointclouds: Explicit, Parametric, Free-Form CAD and Re-engineering,” by Vukašinović, Nikola & Duhovnik, Joze, in the book entitled Advanced CAD Modeling, Springer-Verlag 2019, pp. 217-239, has disclosed a method which automatically reconstructs an object with free-form surfaces in the form of non-uniform rational basis spline (NURBS) from point clouds. However, no parametric model that underlies the point clouds is generated in the process.

The publication “Automatic and Parametric Mesh Generation Approach,” by Alan M Shih, Sankarappan Gopalsamy, Yasushi Ito, Douglas Ross, Mark Dillavou, and Bharat Soni, 2005, describes a method which generates an optimized geometry of a parametric model for a given use purpose on the basis of parameter changes and simulations. However, no automated method is available for imported object geometries.

The publication “Development of Parametric Mesh Morphing Techniques,” by Makoto Onodera, Ichiro Nishigaki, Yoshimitsu Hiro, and Chikara Kongo, Transactions of the Japan Society of Mechanical Engineers Series C. 74, 2008, pp. 1894-1600, has described a method which identifies geometric features of a mesh in the form of plane surfaces, quadrics or free-form surfaces.

US 2016/0327811 A1 has described a method for fitting spectacle frames. However, the spectacle frames are not available here as a parametric model which is altered on the basis of its parameters but are deformed directly. Only elastic deformations are envisaged in the process. Changing the amount of material is not possible either.

US 2016/0336737 A1 describes the fitting of a spectacle frame on the basis of a parametrizable frame model. However, a parametric spectacle frame model is not generated here from a given parametric spectacle frame model.

EP 2 746 838 A1 has described a fitting system for virtual spectacle frames that is based on a parametric model of the spectacle frame. However, this parametric model is altered directly on the basis of spatial curves and enclosed volumes, and does not serve to generate a parametric equivalent model.

The aforementioned methods therefore do not allow a parametric equivalent model to be generated largely automatically from a given parametric model.

### SUMMARY

It is therefore an object of the disclosure to facilitate a largely automated determination of a parametric equivalent model for a parametric model of a spectacle frame element, the parametric equivalent model having at least one parameter.

This object is achieved by the disclosed method of individualizing a spectacle frame element by fitting a parametric model of a spectacle frame element to the head of a spectacles wearer. Exemplary embodiments and developments of the disclosure are specified below.

The computer-implemented method according to a first aspect of the disclosure for individualizing a spectacle frame element by fitting a parametric model of a spectacle frame element to the head of a spectacles wearer, comprises the following method steps:

specifying a plurality of entities of the parametric model, determining at least one base entity and at least one parametric deformation map for the at least one base entity from the specified entities, the at least one parametric deformation map mapping the at least one base entity on entities of the parametric model. In the process, the parametric equivalent model is determined at least from the at least one base entity and from the at least one parametric deformation map. Moreover, biometric data in relation to the head of the spectacles wearer are provided, and at least one parameter value for the at least one parameter of the parametric equivalent model of the spectacle frame element is determined by optimizing a function which considers at least one surface point of a determined base entity of the parametric equivalent model of the spectacle frame element and biometric data determined in relation to the head of the spectacles wearer.

In this case, biometric data in relation to the head of the spectacles wearer are understood to mean data that describe biological properties of the head, in particular dimensions such as lengths, sizes, distances and ratios on the head, e.g., interpupillary distance, nasal bridge width, and/or ear spacing, but also surface points on the head, e.g., ear support points, nose support points, pupils, models of the head of the spectacles wearer, e.g., 3-D models, in particular meshes, 3-D reconstructions or point clouds of the head or models or dimensions of parts of the head of the spectacles wearer.

In the present case, a spectacle frame element describes a part of a spectacle frame, for example a temple, a nose support area, a bridge, a connection element or a frame front. However, a spectacle frame element may also represent a combination of spectacle frame elements or sections of a spectacle frame element, for example a temple section, or else the entire spectacle frame.

The disclosure understands a parametric model and a parametric equivalent model of a spectacle frame element to be a three-dimensional representation of a spectacle frame element in a computer unit, the representation containing at least one parameter for adjusting features and/or properties of the spectacle frame element or parts thereof, e.g., the temple length or the work angles of the nose support surfaces.

By way of example, a parametric model for a spectacle frame element can be available as a CAD model. In the present case, a CAD model should be understood to mean a representation of 3-D objects that is processable by means of a computer unit, the representation being able in particular to be read into the computer unit and stored in the latter, for example as a file in a hard disk space of the computer unit.

A parametric equivalent model is a parametric model used instead of another parametric model in a process, for example the individualization and fitting of spectacle frame elements, and consequently replacing the other parametric model (base model).

In this case, parameters denote changeable values, on the basis of which the features and/or properties of the spectacle frame element or parts thereof can be influenced. Parameter values denote the specific numerical values that can be used for these parameters.

The disclosure understands an entity of a parametric model or of a parametric equivalent model to be a specific example in the form of a realization of the parametric model or of the parametric equivalent model for selected parameter values. In the process, a parameter value is assigned to each parameter of the parametric model or parametric equivalent model.

The disclosure understands a base entity to be a specific entity of a parametric model which is selected or calculated and which is used to define a parametric deformation map.

A parametric deformation map is a map with parameters which acts on the surface of a given base entity, for example an affine map with parameters. By selecting specific parameter values for the parameters of the map, it is possible to generate a specific map which changes the surface of the base entity. In this way, an entity of the parametric equivalent model is generated, possibly when the further parameter values for the parameters of the parametric equivalent model are defined.

The disclosure is based on the concept of the specification of a plurality of entities of the parametric models allowing a greater degree of automation to be obtained by way of a data-driven determination of the parametric equivalent model. This is because parts of the parametric equivalent model like the at least one base entity, the parametric deformation maps or else a decomposition of the parametric model into segments can be calculated automatically from the plurality of entities. In the process, it is advantageous if the specified entities model the variability of the parametric model of the spectacle frame element to the best possible extent. These steps require a much greater programming outlay if a single entity is used as a starting point since the programmer must themselves create routines for automatically recognizing individual spectacle frame elements and for changing these spectacle frame elements on the basis of parametric deformation maps. By specifying a plurality of entities of the parametric model, it is instead possible to use automated methods, for example machine learning methods, to generate the parametric equivalent model as automatically as possible on the basis of the specified entities.

Moreover, the disclosure is based on the concept of the use of a plurality of entities when calculating the parametric equivalent model allowing the quality of the parametric equivalent model—within the meaning of the greatest possible similarity between the entities generable by the parametric model and the parametric equivalent model—to be improved since recognition routines for identifying individual features which are not data-driven, that is to say defined by the programmer, are susceptible to errors.

Finally, the plurality of entities can be used to determine a parametric equivalent model which allows the entire object to be altered—and not only individual detected geometric features.

The computer-implemented method according to the disclosure for individualizing a spectacle frame element by fitting a parametric model of a spectacle frame element to the head of a spectacles wearer, according to a second aspect, comprises the following method steps:

specifying a plurality of entities of the parametric model;

determining a set of segments for the parametric model of the spectacle frame element;

decomposing the specified entities into the segments from the set of segments;

generating segment entities for each segment from the set of segments by virtue of entities of this segment being selected from the decomposed specified entities; and

determining at least one base segment entity and at least one parametric deformation map for the at least one base segment entity from these segment entities.

In this case, the at least one parametric deformation map maps the at least one base segment entity on segment entities of the parametric model. The parametric equivalent model is determined at least from the set of segments and from the at least one base segment entity and the at least one parametric deformation map for each segment from the set of segments.

Moreover, biometric data in relation to the head of the spectacles wearer are provided, and at least one parameter value for the at least one parameter of the parametric equivalent model of the spectacle frame element is determined by optimizing a function which considers at least one surface point of at least one determined base segment entity of the parametric equivalent model of the spectacle frame element and biometric data provided in relation to the head of the spectacles wearer.

In this case, segments are subsets of a spectacle frame element, for example parts of the frame front or parts of the temple. If only one spectacle frame element is available, for example in the form of the entire spectacle frame, the set of segments may contain, for example, the bridge, the temples or connection points.

A segment entity denotes an entity of a segment of a parametric model or parametric equivalent model.

A base segment entity denotes a base entity of a segment of a parametric model or parametric equivalent model. It is determined from selected segment entities for this segment.

The concept according to a second aspect is based on the idea that higher quality and greater flexibility of the parametric equivalent model can be obtained by virtue of the parametric model of the spectacle frame element being decomposed into segments and at least one base segment entity and at least one parametric deformation map being determined individually for each segment. As a result, this allows the parametric equivalent model to be fitted particularly well to the peculiarities of the respective segment rather than mapping the deformations of the at least one base segment entity of the entire parametric model. This measure facilitates greater variability and adaptability of the parametric equivalent model. Additionally, this also facilitates a reduction in the complexity of the at least one base segment entity and of the parametric deformation maps, and hence of the parametric equivalent model. Additionally, determining parameter values for the parameters of the parametric equivalent model is simplified by a lower-complexity parametric equivalent model, saving computation time.

In this case, the at least one base entity or the base segment entity may be selected or calculated from the specified entities or the segment entities, for example by determining the mean value.

According to a second aspect, the method of individualizing a spectacle frame element by fitting a parametric model of a spectacle frame element to the head of a spectacles wearer by decomposing specified entities is particularly suitable if the parametric model of the spectacle frame element is not yet already available in the form of segments or parts.

According to a third aspect, the computer-implemented method for individualizing a spectacle frame element by fitting a parametric model of a spectacle frame element to the head of a spectacles wearer, comprises:

the determination of a parametric equivalent model for a parametric model of a spectacle frame element, the parametric equivalent model having at least one parameter, by virtue of a set of segments being determined for the parametric model of the spectacle frame element, a parametric segment model from the parametric model of the spectacle frame element being determined for each segment, a parametric equivalent model having at least one parameter being determined as a segment equivalent model for each parametric segment model in a computer-implemented method according to the first aspect, and the parametric equivalent model being determined at least from the set of segments and from the parametric segment equivalent models having at least one parameter.

Moreover, biometric data in relation to the head of the spectacles wearer are provided, and at least one parameter value for the at least one parameter of the parametric equivalent model of the spectacle frame element is determined by optimizing a function which considers at least one surface point of a determined base entity of a segment equivalent model of the parametric equivalent model of the spectacle frame element and biometric data provided in relation to the head of the spectacles wearer.

In this case, a parametric segment model denotes a parametric model which describes only one segment of the spectacle frame element. It can be determined from the parametric model of the spectacle frame element, for example if the latter is already given in the form of parts.

The method according to the third aspect is based on a similar concept as the method according to the second aspect, specifically the decomposition of the parametric equivalent model into segments with the aforementioned advantages. While entities of the parametric model of the spectacle frame element which are subsequently decomposed into segments are generated in the method according to the second aspect, the parametric model itself is decomposed into segments in the method according to the third aspect, and so a parametric segment model can be determined for each segment. Then, a dedicated segment equivalent model is determined for each parametric segment model in the computer-implemented method according to the first aspect. This procedure is especially advantageous if the parametric model of the spectacle frame element is already available in the form of segments.

By way of example, spectacle frame elements can be represented in the form of meshes or point clouds in computer units. Preferably, these objects are available as meshes. Otherwise, a mesh can initially be generated by means of triangulation, for example from a given point cloud.

In particular, meshes are triangular meshes which comprise surface points in the form of nodes, normal vectors at the nodes and triangular surfaces. A continuous representation of such a triangular mesh can be generated on the basis of shading algorithms.

In addition to the representation on the basis of triangular meshes, there are also other polygonal or volume-based representation forms of meshes, as explained for example in the Wikipedia article “Types of Meshes” dated Jul. 11, 2019 (en.wikipedia.org/wiki/Types_of mesh). By way of example, two-dimensional meshes can be constructed from triangular or else quadrilateral cells. Three-dimensional meshes may consist of pyramidal, cuboid or prism-shaped cells.

An entity of the parametric equivalent model of the spectacle frame element can be generated on the basis of the parametric equivalent model for a spectacle frame element and a given set of parameter values for the parameters of the parametric equivalent model. The latter contains a set of surface points in the form of 3-D points on the surface of the at least one spectacle frame element.

According to the disclosure, a parametric equivalent model for a parametric model of a spectacle frame element, the parametric equivalent model having at least one parameter, is determined in a computer-implemented method for individualizing the spectacle frame element by fitting the parametric model of the spectacle frame element to the head of a spectacles wearer.

In the process, biometric data relating to the head of the spectacles wearer are also determined. The biometric data relating to the head of the spectacles wearer may consist of at least one surface point of a representation, e.g., a mesh, of the head of the spectacles wearer. These data may be available in a computer unit, for example in the form of surface points of the head of the spectacles wearer in a coordinate system. By way of example, this can be obtained by recording the head from different recording directions by means of an image processing device and by calculating a 3-D model of the head on the basis of a 3-D reconstruction method or by means of a simultaneous localization and mapping (SLAM) method. So as not to have to calculate a full 3-D model, so as to minimize errors and so as to save computation time, it is also possible to determine only a few 3-D points of the head and fit a head model determined from a multiplicity of exemplary data thereto. By way of example, this head model can be determined using machine learning methods. Alternatively, a 3-D model of the head can also be loaded into the computer unit from a storage medium or via the network. In this case, the head of the spectacles wearer is preferably available in a computer unit as a mesh. Alternatively or in addition, dimensions of the head, for example the ear spacing, the nasal bridge width or other length dimensions on the head, can also be determined as biometric data of the head of the spectacles wearer.

Then, at least one parameter value for the at least one parameter of the parametric equivalent model of the spectacle frame element is determined in a second step such that the entity of the parametric equivalent model of the spectacle frame element generated on the basis of this at least one parameter value is fitted to the head to the best possible extent. The at least one parameter value is determined by optimizing a function which takes into account at least one surface point of a determined base entity of the parametric equivalent model of the spectacle frame element and biometric data determined in relation to the head of the spectacles wearer. In this case, the biometric data in relation to the head of the spectacles wearer can be available as length and distance measures or, alternatively or in addition, in the form of surface points of the head, for example as individual points such as ear support points, or as a point cloud which represents a part of the head or the entire head. In this case, it is advantageous for the function to be optimized to also take account of parameters of the at least one parametric deformation map of the parametric equivalent model, the deformation map influencing the relative position of the surface points of the at least one base entity. The function to be optimized can minimize the distance between point clouds, for example between a first point cloud which consists of at least one surface point of a base entity of the parametric equivalent model or a base segment entity of the parametric equivalent model and a second point cloud which consists of at least one surface point of a representation, e.g., a mesh, of the head of the spectacles wearer. The function to be optimized may also consider individual specific points of the head of the spectacles wearer and/or of a base entity of the parametric equivalent model of the spectacle frame element, for example the support points on the spectacle frame element at the ear or on the nose, and the corresponding support points on the head of the spectacles wearer. The spectacle frame element can be fitted to the head by minimizing the distances between corresponding support points. The entity of the parametric equivalent model of the spectacle frame element generated on the basis of the at least one parameter value is then fitted to the head. Alternatively, the function to be optimized may also only adjust parts of a base entity of the parametric equivalent model of the spectacle frame element on the basis of biometric data of the head, the parts being the temple length or the bridge width, for example. The function may also take account of dimensions of the head of the spectacles wearer or of the parametric equivalent model of the spectacle frame element, for example the width of the nasal bridge, the bridge width, lens dimensions or the ear point spacing. The function to be optimized may also contain parameters which adjust the relative position of a base entity of the parametric equivalent model of the spectacle frame element in relation to surface points of the head, for example rotation, translation and scaling parameters. Alternatively, adjusting the parametric equivalent model on the basis of the biometric data in relation to the head of the spectacles wearer can also be carried out by means of entries of a user via a user interface of the computer unit. Further adjustment methods and details in this respect are described in US 2018/0336737 A1, EP 2 746 838 A1 and US 2016/0327811 A1, to which reference is made herewith and the disclosure of which is incorporated in the description of this disclosure.

Probability distributions or value ranges in relation to parameters of a parametric model or a parametric equivalent model may be given or may be determined. In this case, a value range is a continuum of parameter values bounded by a minimum value and a maximum value. Alternatively, it may also be available as a set of discrete parameter values, for example by sampling a continuous value range between the minimum value and maximum value, for example at equidistant intervals. If a probability distribution is provided for a parameter, it is advantageous to choose parameter values that have a greater probability. Value ranges or probability distributions for the parameters of the model can also be determined on the basis of a specified set of entities of the parametric model or the parametric equivalent model.

In the present case, a probability distribution for a parameter of a parametric model or parametric equivalent model is understood to mean a description of the frequency with which individual parameter values occur during the generation of different entities. If the value of the probability distribution for a specific value of a parameter is large, this means that the value of this parameter is typical for many entities. By contrast, if the value of the probability distribution for a certain parameter is small or if the value of the probability distribution for a certain parameter tends to zero, this means that the value of this parameter does not occur for a large number of entities.

Determining the value ranges and/or probability distributions for parameters improves the manageability of the parametric equivalent model for the user since parameter values that generate unrealistic or undesirable entities are excluded in advance.

The generation of entities on the basis of value ranges or probability distributions for the parameters of the parametric model can be implemented automatically, for example by selecting the mean value, median or expected value. Alternatively, parameter values can also be chosen manually by the user by way of a user interface.

Adjustments of a parametric model of a spectacle frame element can be brought about by means of parametric maps, which for example are applied to all surface points or to subsets of the surface points of the mesh of the spectacle frame element. By adjusting the values of all parameters or individual parameters of these maps it is possible to modify the spectacle frame element.

For a given entity of a parametric model or a parametric equivalent model, a change in a parameter value brings about a change in the surface points of the entity.

The parametric equivalent model may contain the same parameters as the parametric model or it may contain different parameters, additional parameters or only a subset of the parameters of the parametric model.

The parametric equivalent model may contain the following elements, each of which may have parameters:
the set of segments;
the number of segments;
the at least one base entity or base segment entity as a mesh;
the at least one base entity or base segment entity in the form of an index which labels the selected base entity or base segment entity within the specified entities or segment entities;
a computing rule which allows the determination of the at least one base entity or base segment entity, in particular on the basis of the specified entities or segment entities, for example by calculating the mean value of the specified (optionally normalized) entities or segment entities;
the at least one parametric deformation map;
additional features such as ear support points, nose support points, support curves of the ends of the temples; 3-D lens planes as approximation for the lenses to be fitted into the spectacle frame, 3-D boxes for approximating the rims of the frame front, nose pads;
a post-processing routine;
value ranges and/or probability distributions over the parameter values of the parametric equivalent model.

So that the parametric equivalent model is usable as a replacement for a parametric model, it is advantageous if the quality of the parametric equivalent model is as high as possible, that is to say that an entity of the parametric equivalent model can be produced for each entity of the parametric model, in such a way that the deviation between the two entities is the smallest possible.

The deviation between two entities can be determined on the basis of their surface points. It can be calculated as a criterion from the group comprising weighted sum, mean, maximum or quantile of the distribution of the smallest deviations between the surface, e.g., the surface points, of the one entity and the surface of the other entity. The deviation between two entities can be determined, for example, as a one-sided Hausdorff distance or a two-sided Hausdorff distance, as described in, for example, N. ASPERT et al. “Measuring Errors between Surfaces using the Hausdorff Distance,” Proceedings IEEE International Conference on Multimedia and Expo Lausanne, Switzerland (2002) on pages 1 to 4, to which reference is made herewith and with the disclosure of this publication being included in the description of this disclosure.

The one-sided Hausdorff distance h corresponds to the maximum of all smallest distances d: [symbol] ³× [symbol] ³→ [symbol] of the one entity S from the other entity S′, for example the maximum of the Euclidean distances of the surface points of the one entity S from the respective closest surface point of the other entity S′:

$$h ( S , {S}^{′} ) = {max}_{p ∈ S} {min}_{{p}^{′} ∈ {S}^{′}} d ( p , {p}^{′} ) .$$

The two-sided Hausdorff distance H(S,S′) by contrast describes the maximum of the two one-sided Hausdorff distances between the surfaces S and S′:

$$H ( S , {S}^{′} ) = max \{ {max}_{p ∈ S} {min}_{{p}^{′} ∈ {S}^{′}} d ( p , {p}^{′} ) , {max}_{{p}^{′} ∈ {S}^{′}} {min}_{p ∈ S} d ( p , {p}^{′} ) \} .$$

As an alternative to the deviations between surface points of the entities, it is also possible to determine deviations between the surfaces themselves, for example on the basis of the triangles of the meshes or on the basis of the skeletons of the entities determines by means of a skeletonization method.

To measure the quality of a parametric equivalent model of a spectacle frame element, it is possible to define quality criteria for the parametric equivalent model of the spectacle frame element on the basis of a set A of entities of the parametric model of the spectacle frame element, for example the specified entities and/or further entities not used to generate the parametric equivalent model, and a set B of entities of the parametric equivalent model of the spectacle frame element. In this case, for each entity of the set A, the set B comprises an entity which was generated on the basis of the parametric equivalent model of the spectacle frame element and which has the smallest possible deviation between the surfaces.

In this case, a quality criterion may have a continuous value range, for example in the form of the maximum or average deviation between the entities of the set A and the entities of the set B.

Alternatively, use can also be made of a binary value quality criterion, which is either satisfied or not satisfied. By way of example, such a quality criterion can be formulated in the form of conditions that a parametric equivalent model has to satisfy in order to meet the quality demands of the user. By way of example, maximum admissible deviations can be defined for different regions of the parametric model of the spectacle frame element, which deviations may occur between entities of the set A and entities of the set B in the specified regions. By way of example, a maximum admissible deviation of 0.05 mm may be defined for the surfaces in the region of the nose support areas and a maximum deviation of 0.5 mm may be defined for surfaces in the region of the temples.

The disclosure understands an optimization of a continuous quality criterion to be the maximization or minimization thereof by adjusting the elements of the parametric equivalent model of the at least one spectacle frame element, for example the at least one base entity, the set of segments or the parametric deformation maps. The disclosure understands an optimization of a binary value quality criterion to be the adjustment of the parameters of the parametric equivalent model of the at least one spectacle frame element until the specified conditions are met.

A value range and/or a probability distribution over the parameter values can be determined for each parameter of the parametric equivalent model of the at least one spectacle frame element. To this end, a plurality of entities, for example the specified entities, can be represented on the basis of the parametric equivalent model. Then, value ranges or probability distributions for the parameters of the parametric equivalent model can be determined from the parameter values associated with the specified entities.

An equivalent model of at least one spectacle frame element determined in an above-described method offers in particular the following advantages:

As a result of a high degree of automation of the method, there is little outlay for the user in relation to the generation of the parametric equivalent model of the at least one spectacle frame element. In particular, use can be made here of machine learning methods which generate the parametric equivalent model largely automatically on the basis of the specified entities.

Moreover, the method requires only short computation times since the individual steps of the method are able to be carried out particularly efficiently. By way of example, the base entity and the parametric deformation maps can be determined simply by way of selection.

In addition, the generated parametric equivalent model of the at least one spectacle frame element is of particularly high quality, within the meaning that an entity generated on the basis of the given parametric model of the spectacle frame element is also representable with a small deviation on the basis of the parametric equivalent model. The smaller the deviation, the higher the quality of the parametric equivalent model because this makes it more suitable as a replacement for the parametric model.

Moreover, the generated parametric equivalent model is less complex on account of its structure of definite base entities and parametric deformation maps. This facilitates particularly quick fitting of the parametric equivalent model to the head of a spectacles wearer since the optimization of a system of little complexity requires less complex algorithms for optimization purposes and hence also less computation time. Moreover, the low complexity of the parametric equivalent model facilitates particularly fast processing of parameter changes. This is because a system for individualizing a frame is only accepted by customers and opticians if the results of parameter change within the adjustment process are immediately visible on the screen. However, the calculation of a new entity in the case of a parameter change often requires several seconds computation time in the case of complex parametric models.

Entities of the parametric equivalent model of the at least one spectacle frame element only require little memory space when represented in a memory of a computer unit. This is because it is not the entire mesh that is stored but only the parameter values of the elements of the parametric equivalent model, for example the index of the selected base entity if more than one base entity is contained in the parametric equivalent model, or the parameter values of the at least one parametric deformation map. As a result, it is possible to store databases with many spectacle frame models or spectacle frame element models without much difficulty. At the same time, this measure reduces the transmission time between fitting and ordering systems. Moreover, the parametric equivalent model is therefore also suitable for compressing entities of the parametric model. This is because entities of the parametric model can be represented as entities of a parametric equivalent model for the parametric model, with only the parameter values for the entities of the parametric equivalent model needing to be stored instead of the entire mesh.

The parametric equivalent model offers the user great flexibility in the generation of entities. This is because it is not only possible to choose entities from a specified stored set of entities of the parametric model of the spectacle frame element, but also possible to generate entities for any parameter values, e.g., intermediate values. By way of example, if entities of a parametric model of a temple with different lengths are given, it is possible to generate entities with further lengths on the basis of the parametric equivalent model. In comparison with the specified entities, the parametric equivalent model can also be fitted to the head of the spectacles wearer with greater accuracy as a result.

On account of these advantages, the generated parametric equivalent model of the spectacle frame element and the method for the generation thereof can be handled more comfortably by the user.

The specified entities of the parametric model of a spectacle frame element can be selected from a set of entities of the parametric model. This set can be generated on the basis of the modeling system in which the parametric model was generated. On the basis of this set of specified entities, it is possible to optimize individual method steps in order to ensure a higher quality of the parametric equivalent model.

In this case, it is advantageous if the set of the specified entities contains at least two entities of the parametric model of the spectacle frame element generated on the basis of different parameter values. Each specified entity represents a specific realization of the parametric model for a selected set of parameter values. By way of example, the boundaries of the value ranges of the parameters or mean values or medians thereof can be chosen as parameter values. Alternatively, the entities may also be determined by a random selection of parameter values.

Let n be the number of parameters of the parametric model, then a total of k parameter values are selected for each parameter within the corresponding parameter range. A set of specified entities is generated from all combinations of these parameter values, the set consequently containing kⁿ entities. Advantageously, k=2 parameter values are selected for each parameter, for example on the basis of one parameter value from the upper limit of the value range of the parameter and one from the lower limit of these value range. A number of k=5 parameter values per parameter is even more advantageous. It is also possible to select a different set of parameter values for each parameter.

The specified entities are preferably located in a common coordinate system, for example in the coordinate system of the parametric model of the spectacle frame element. Further preferably, the specified entities of the parametric model are positioned and oriented in the coordinate system, in such a way that the centroid of the respective entity corresponds with the center of the coordinate system. Additionally or as an alternative, a plane of symmetry of the respective entity may contain one or two axes of the coordinate system.

By way of example, the alignment can be calculated on the basis of a principal component analysis by virtue of determining the first two (orthogonal) principal components of the points of the mesh and transforming all points of the mesh in such a way that the two principal components are mapped to the coordinate axes, for example the first principal component to the applicate axis and the second principal component to the ordinate axis.

These alignment measures are advantageous in that the parametric equivalent model is of the highest possible quality and in that the generation thereof requires as little computation time as possible and can be carried out in automated fashion to the greatest possible extent.

The generation of the specified entities can be implemented in automated fashion on the basis of a computer program, saving computation time and outlay for the user. Moreover, this measure contributes to a high degree of automation of the method.

It is advantageous if the specified entities of the parametric model are at least partly post-processed by means of an algorithm for rectifying errors and/or for improving the visual impression for the spectacles wearer and/or for smoothing. Errors can be, e.g., topological defects such as holes or an irregular triangulation, for example an irregular density or size of the surface triangles of the mesh. A higher quality of the parametric equivalent model generated on the basis of the specified entities can be obtained on the basis of this pre-processing step.

The elements of the parametric equivalent model can be determined on the basis of the specified entities. This determination can be implemented manually by the programmer or user, or automatically on the basis of machine learning methods. For determining the parametric equivalent model, e.g., of the at least one base entity, the at least one parametric deformation map or the set of segments, it is advantageous here for a criterion to be optimized from the group comprising weighted sum, average, maximum and quantile of the distribution of the deviations between the surfaces, e.g., the surface points, of the specified entities of the parametric model and the surfaces of all those entities of the parametric equivalent model of the at least one spectacle frame element which are generable on the basis of specific parameter values.

Moreover, it is advantageous if a method for recognizing points of inflection in signals and/or a mesh segmentation method and/or a multivariate fitting method and/or a skeletonization method and/or a machine learning method is applied during the decomposition of entities of the parametric model of the spectacle frame element into segments from the set of segments.

To automatically decompose entities of the parametric model of the spectacle frame element into segments from the set of segments on the basis of a method for detecting points of inflection, the surface points of the entity along a spatial axis are projected onto a plane. From the projection points, it is possible to select a subset on the basis of an algorithm, the preimage of which subset is associated with a contour of a spectacle frame element. This subset of projection points can be understood to be a sequence of discrete sampling values of a signal. Then, points of inflection of this signal can be determined by means of an algorithm. These points of inflection are finally used to determine the boundaries of the segments from the set of segments.

This procedure is advantageous in that the decomposition of the entities can be implemented in fully automated fashion. This is because the algorithm for detecting points of inflection requires no semantic information about the nature of the individual segments or their boundaries, or about how these can be found in the data. This significantly reduces the outlay for the user.

Alternatively, it is also possible to use machine learning methods for automatically decomposing entities into segments from the set of segments.

Alternatively, it is also possible to use other mesh segmentation methods, for example as described in the article “A Survey on Mesh Segmentation Techniques, Ariel Shamir, Computer Graphics Forum, vol. 27, no. 6, 2008, pp. 1839-1856.” It is also possible to use multivariate adjustment methods, as presented in the book “Using Multivariate Statistics, Barbara G. Tabachnick, Linda S. Fidell, Jodie B. Ullman, Pearson Verlag, 2007.”

As an alternative, it is also possible that skeletonization methods, as described in the article “Skeleton Extraction by Mesh Contraction, Oscar Kin-Chung Au, Chiew-Lan Tai, Hung-Kuo Chu, Daniel Cohen-Or, Tong-Yee Lee, Proceedings of SIGGRAPH 2008,” serve to segment entities.

Comprehensive reference is herewith made to the aforementioned book and the two articles, and the disclosure thereof is included in the description of this disclosure.

On the basis of a skeletonization method, it is possible for the mesh of an entity, for example, to generate a structure of little complexity in the form of a skeleton. In this case, the skeleton of a three-dimensional object comprises all interior points of the object which are a center point of a maximum sphere contained within the object.

Each surface point of the entity can then be assigned to a closest point of the generated skeleton. Instead of the mesh of the entity, it is now possible to decompose the less complex skeleton of this entity into regions. All surface points associated with a region of the skeleton then form a segment. This procedure saves computation time.

A further advantage is that the generated skeleton can also be used in the subsequent method step for determining the parametric deformation maps. This is because mapping an entity on another on the basis of the associated skeletons likewise saves complexity and computation time.

The at least one parametric deformation map serves to map a base entity or a base segment entity on further entities or corresponding segment entities of the parametric model of the at least one spectacle frame element. In this case, the parametric deformation maps are defined in the form of functions with parameters to be determined.

By way of example, affine maps which describe a rotation, a translation and a scaling of the segments can be chosen as parametric deformation maps.

It is advantageous if the parametric deformation maps of the parametric equivalent model originate from the group comprising affine maps, polynomials, polynomial surfaces, Bezier curves, splines or NURBS. This can achieve a higher quality of the parametric equivalent model and a short computation time during the representation or fitting of spectacle frame elements to the head.

At the same time, the degree of automation of the method can be increased for example by the choice of the parametric deformation maps with little complexity and few parameters, for example affine maps. This is because in this case the parameter values of the parametric deformation maps can be determined automatically on the basis of an algorithm for minimizing the deviation between entities of the parametric model and of the parametric equivalent model.

Moreover, machine learning methods can be used to determine the elements of the parametric equivalent model, in particular the at least one base entity and the at least one parametric deformation map. Preferably, principal component analysis can be used in this case.

To this end, the specified entities are represented by point clouds or voxel grids. These may be represented as a vector, which for example contains the coordinates of the points or information for each voxel as to whether it is located within or outside the spectacle frame element. The vectorized specified entities of the parametric model can be used to determine the mean value of the specified entities first. This then forms the base entity. The mean value can be subtracted from each of the specified entities and the covariance matrix of the entities can be calculated therefrom. Diagonalization thereof allows the eigenvectors and eigenvalues of the covariance matrix to be determined. To achieve a lower complexity of the parametric equivalent model, it is possible to choose only eigenvectors for large eigenvalues. The specified entities and further entities I of the parametric model or its segments can now be represented approximately by parametric deformation maps in the form of a linear combination of the base entity b as a mean value and the n eigenvectors vᵢ:

$$I = f ( b , α ) = b + {\sum }_{i = 1}^{n} {α}_{i} {v}_{i}$$

The parametric equivalent model then consists of the base entity b and the eigenvectors vᵢ. Then, to represent a specific entity on the basis of the parametric equivalent model, the parameter values αᵢ of the parametric deformation maps are determined. Neural networks can also be used for automatically calculating the base entity and the deformation maps.

Preferably, the parametric equivalent model is stored in the memory of a computer unit.

An advantage of the method is that it is applicable to parametric models of at least one spectacle frame element with a surface of any genus. The genus of a surface is defined as the maximum number of possible cuts along disjoint, closed simple curves such that the surface still is contiguous once all cuts have been made. Consequently, it denotes the number of holes in the surface. This improves the handling of the method for the user since the method is not restricted to a class of spectacle frame elements with a specific genus.

It is advantageous if the segments from the set of segments of the parametric equivalent model are labeled static, movable or deformable.

Labeling can be carried out automatically on the basis of a clustering method which analyzes contiguous surface points on the basis of the movement by means of various entities of the parametric model of the spectacle frame element, for example the specified entities.

On the basis of this label, it is possible to improve the quality of the parametric equivalent model since the parametric deformation maps can be suitably selected on the basis of the movement of the respective segment.

When selecting the segment entities from the specified entities decomposed into segments, one segment entity is sufficient for segments labeled static. For segments labeled movable or deformable, it is advantageous for the accuracy of the parametric equivalent model if at least two segment entities, preferably five segment entities, are present.

Furthermore, it is particularly advantageous if the parametric deformation maps of the segments labeled as static are linear maps and/or if the parametric deformation maps of the segments labeled as movable are affine maps and/or if the parametric deformation maps of the segments labeled as deformable are approximated on the basis of polynomials, polynomial surfaces, Bézier curves, splines or NURBS.

As a result, the complexity of the parametric deformation maps is reduced by adaptation to the movement of the segments. This saves computation time and improves the quality of the parametric equivalent model.

Preferably, when the parameters of the parametric equivalent model of a spectacle frame element are changed, the triangular structure of the mesh, that is to say the topology and linking of the triangles, is not recalculated but maintained. This dispenses with the time-intensive step of triangulating the surface points for adjusting the triangular mesh. This saves computation time and at the same time leads to a parametric equivalent model of the spectacle frame element with less complexity.

An advantageous development of the disclosure provides for method steps for determining the parametric equivalent model to be iterated. This measure ensures a higher quality of the parametric equivalent model since the individual elements of the parametric equivalent model are dependent on one another and are able to be optimized better in this way.

Advantageously, the segments from the set of segments are arranged hierarchically in a tree structure in such a way that the nodes connected in the tree structure are associated with segments with a common cut edge or cut surface in the parametric model. Interconnected nodes of the tree consequently indicate a spatial neighbourhood of the associated segments.

Further, it is advantageous if each segment in the tree structure is positioned and oriented relative to its parent segment in a coordinate system. In this case, the segments may contain a dedicated local coordinate system and, additionally, the position and orientation relative to the superordinate segment in the tree structure. As a result of the relative orientation of the segments with respect to one another, this overall leads to a composition of rigid body transformations, which is used to adjust the base entity for the spectacle frame element. By way of example, the rigid body transformations can be encoded as a kinematic chain, as described in the “Forward Kinematics” Wikipedia article dated Jun. 28, 2019.

The hierarchic arrangement of the segments simplifies the calculation of the parameter values of the parametric equivalent model since these can be determined incrementally for the individual nodes along the hierarchy of the tree structure and can be determined on the basis of the calculated parameter values of the parent node. This saves computation time and improves the quality of the parametric equivalent model.

If at least two spectacle frame elements are present, these can be arranged in a hierarchical tree structure in addition or as an alternative to the segments.

Since parameter values are determined independently of the other segments for each segment of the at least one base entity of the at least one spectacle frame element, there may be discontinuities at the segment boundaries. To improve the quality of the parametric equivalent model and the visual impression for the spectacles wearer, it is possible that entities of the parametric equivalent model are post-processed on the basis of an algorithm for avoiding discontinuities at segment boundaries. This measure can be provided in an additional method step.

The post-processing step of the parametric equivalent model of the at least one spectacle frame element may moreover contain an algorithm for rectifying errors and/or for improving the visual impression for the spectacles wearer and/or for smoothing the mesh.

By way of example, a smoothing method can be chosen as a post-processing step. The type of post-processing method and its parameters can be determined and can be stored in addition in the parametric equivalent model.

Moreover, the integration of assumptions of symmetry in relation to individual segments, for example of the left and the right temple, into the parametric equivalent model is advantageous. By way of example, to create a parametric equivalent model of an entire spectacle frame, the symmetry thereof means that it is sufficient for only a parametric equivalent model of the left or right temple to be available. An entity of the respective other temple can be determined by reflection in the plane of symmetry of the spectacle frame and alignment on the frame front. This measure can save computation time and memory space and transmission time.

In the case of a rather small variation in the parametric model of a spectacle frame element, it is likewise possible to reduce the complexity of the parametric equivalent model of the at least one spectacle frame element in order to save computation time and optionally outlay for the user. To this end, a relatively large set of base entities for the parametric equivalent model of the spectacle frame element is chosen in such a way that it represents the variational range of the spectacle frame element to the best possible extent.

Spectacle frame elements with a small variation, for example the temples which usually only vary in terms of overall length, can thus be selected directly by selection from a set of base entities, for example a set of base entities for different temple lengths. In this way, there is no need to determine parametric deformation maps and calculate the parameter values thereof on the basis of algorithms.

An exemplary embodiment of the disclosure furthermore provides for additional features from the group comprising ear support points, nose support points, support curves of the ends of the temples, 3-D lens planes, 3-D boxes, nose pads to be calculated for the parametric equivalent model of the spectacle frame element. These additional features make fitting the parametric equivalent model of the spectacle frame element to the head of the spectacles wearer easier on the basis of certain orientation points detected on the head model of the spectacles wearer. This improves the manageability of the parametric equivalent model for the user.

The disclosure understands data format to mean the representation of information or data that is processable by means of a computer unit, the representation being able in particular to be read into the computer unit and stored in the latter, for example as a file in a hard disk space of the computer unit.

It is advantageous if the parametric equivalent model is provided in a data format that differs from that of the parametric model, in particular in a data format that is independent of the system in which the parametric model was generated. By way of example, if the parametric model is available as a CAD model, the parametric equivalent model can be provided in a data format which is adapted to the specific system in which the parametric equivalent model should be used, for example to the fitting system for fitting a spectacle frame element to the head of a spectacles wearer.

Determining a parametric equivalent model with a format-independent representation is simplified by specifying entities of the parametric model. The parametric model then is available in a specific format, for example in the format of the modeling program used by the designer. However, the specified entities are available as a mesh. Hence, they are independent of the format of the modeling program and can be stored in a different data format.

An advantageous development provides for the use of a parametric equivalent model for a parametric model of a spectacle frame element, the parametric equivalent model having at least one parameter, in a computer-implemented method for representing and/or compressing a given entity of the parametric model of the spectacle frame element in a computer unit.

In this case, a respective parameter value for the at least one parameter of the parametric equivalent model of the spectacle frame element is determined in a first step by optimizing a criterion from the group comprising weighted sum, average, maximum and quantile of the distribution of the deviations between surfaces, e.g., surface points of the given entity of the parametric model and surfaces, e.g., surface points of the entity of the parametric equivalent model generated on the basis of this at least one parameter value. The at least one determined parameter value can then be stored in a memory of the computer unit.

This method is advantageous in that a given entity of a parametric model of the at least one spectacle frame element can be represented on the basis of very few parameter values if a parametric equivalent model of the at least one spectacle frame element is available. As a result, an entity can be stored in a very memory space saving fashion. Particularly in the case of relatively large sets of entities in a frame database, this allows the memory requirement to be significantly reduced. On account of the smaller amount of data, this can also be accompanied by a significant reduction in the transmission time for fitted spectacle frame elements, for example between a fitting system at an optician and an ordering system or a private computer unit of the spectacles wearer.

In the method for individualizing a parametric model of at least one spectacle frame element and/or in the method for representing and/or compressing entities, and when transferring entities, of a parametric model of a spectacle frame element, it is advantageous if distances between point clouds are minimized when optimizing the at least one parameter of the parametric equivalent model.

In the method for individualizing a parametric model of a spectacle frame element, the point clouds are given as surface points of the base entity of the parametric equivalent model and as surface points of the mesh of the head of the spectacles wearer. In this case, the distance between an ear support point on a temple and surface points on the ear of the spectacles wearer, for example, is minimized.

In the method for representing and/or compressing entities of a parametric model of a spectacle frame element, the point clouds are given as surface points of the selected base entity of the parametric equivalent model of the spectacle frame element and as surface points of the entity to be represented and/or compressed. In this case, the deviation of all surface points of the two entities is minimized, for example using the Hausdorff distance.

A method for minimizing distances between point clouds is, e.g., the iterative closest point (ICP) algorithm, which is described together with various variants in the article “Efficient Variants of the ICP Algorithm, Szymon Rusinkiewicz, Marc Levoy, Proceedings of the 3DIM Conference, Quebec, 2001, pages 145-182,” the entirety of which is referred to herewith and the disclosure of which is included in the description of this disclosure.

This algorithm is advantageous in that the parameter values of the parametric equivalent model can be determined particularly accurately and with as little outlay and computing time as possible. This improves the quality and the manageability of the parametric equivalent model.

A computer program product according to the disclosure contains a computer program with program code for carrying out the aforementioned method steps when the computer program is loaded into a computer unit and/or executed on a computer unit.

An apparatus for individualizing and fitting a parametric model of a spectacle frame element to the head of a spectacles wearer contains a computer unit, loaded in which there is a computer-implemented method for fitting the parametric model of the spectacle frame element to a representation of the head in a coordinate system.

An apparatus for representing and/or compressing a given entity of a parametric model of a spectacle frame element contains a computer unit having a memory, loaded in which there is a computer-implemented method for representing and/or compressing the given entity in the memory of the computer unit.

A system according to the disclosure having a device for producing a spectacle frame element individualized in an above-described method for individualizing a spectacle frame element or for grinding spectacle lenses into a spectacle frame element individualized in an above-described method for individualizing a spectacle frame element uses the at least one determined parameter value of the parametric equivalent model.

### BRIEF DESCRIPTION OF THE DRAWINGS

Below, exemplary embodiments of the disclosure, which are schematically depicted in the drawings, are described:

FIG. 1 shows a parametric model of a spectacle frame element in the form of a CAD model of a spectacle frame with different further spectacle frame elements;

FIG. 2 shows a mesh of a spectacle frame element with surface points and a triangular mesh;

FIG. 3 shows a method for individualizing a spectacle frame element by fitting a parametric model of a spectacle frame element to the head of a spectacles wearer;

FIG. 4 shows a method for determining a parametric equivalent model of a spectacle frame element in the form of a temple;

FIG. 5 shows an alternative method for determining a parametric equivalent model of a spectacle frame element in the form of a frame front;

FIG. 6 shows a further alternative method for determining a parametric equivalent model of a spectacle frame element in the form of a frame front;

FIG. 7 shows a coordinate system for arranging entities on the basis of their centroid and plane of symmetry;

FIG. 8 shows entities of a CAD model of a frame front and a temple;

FIG. 9 shows the determination of a base entity of a CAD model of a frame front on the basis of specified entities;

FIG. 10 shows a decomposition of an entity of a CAD model into segments from the set of segments;

FIG. 11 shows the determination of a parametric equivalent model of a CAD model of a frame front with a base entity and a parametric deformation map on the basis of specified entities by means of principal component analysis;

FIG. 12 shows method steps for determining a parametric equivalent model of a spectacle frame element on the basis of specified entities;

FIG. 13 shows an arrangement of segments from the set of segments of a parametric equivalent model of a spectacle frame element in a hierarchic tree structure;

FIG. 14 shows a method for individualizing a spectacle frame element;

FIG. 15 shows a method for representing and/or compressing an entity of a parametric model of a spectacle frame element;

FIG. 16 shows projection points generated by projecting surface points of a mesh of a frame front into a plane;

FIG. 17 shows an upper and a lower rim of an entity of a CAD model of a frame front;

FIG. 18 shows a signal consisting of partial signals and points of inflection;

FIG. 19A, FIG. 19B, and FIG. 19C show calculated points of inflection and mean values of partial signals for projected surface points of an upper and lower spectacle rim;

FIG. 20A and FIG. 20B show a decomposition of two entities of a parametric equivalent model of a frame front on the basis of determined points of inflection in signals;

FIG. 21 shows a decomposition of an entity of a CAD model of a temple into two segments;

FIG. 22 shows the optimization of the decomposition of an entity into segments by varying the parameter values of the segmentation;

FIG. 23A, FIG. 23B, and FIG. 23C show the determination of parameter values of a parametric deformation map for a base segment entity of a CAD model of a temple and the corresponding segment of a further entity on the basis of an ICP algorithm;

FIG. 24A, FIG. 24B, and FIG. 24C show the determination of parameter values of parametric deformation maps for base segment entities of a CAD model of a frame front and the corresponding segments of a further entity;

FIG. 25 shows method steps for generating a mesh on the basis of a parametric equivalent model and given parameter values; and

FIG. 26A, FIG. 26B, and FIG. 26C show the smoothing of an entity of a parametric equivalent model of a connection element on the basis of a post-processing step for smoothing at segment boundaries.

### DESCRIPTION OF EXEMPLARY EMBODIMENTS

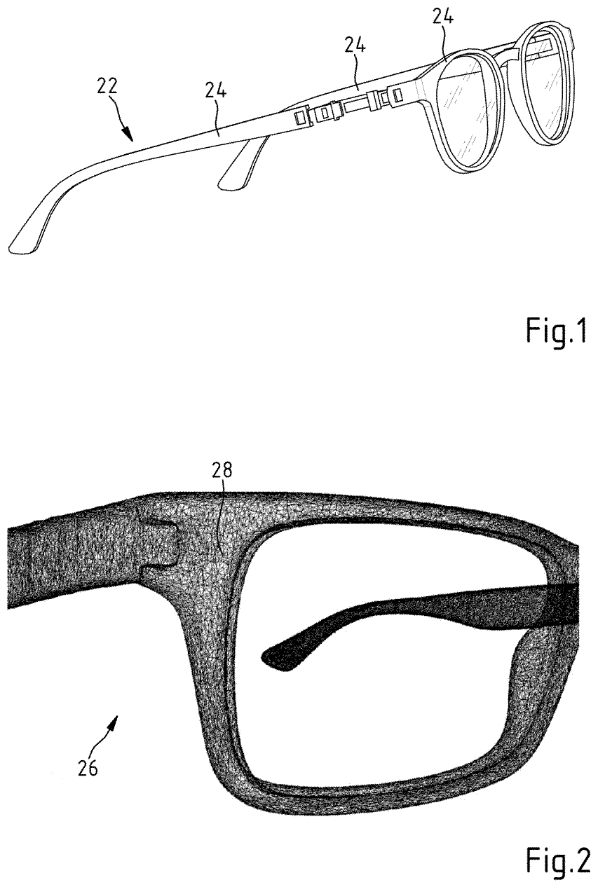

FIG. 1 shows a parametric model of a spectacle frame element 24 in the form of a CAD model 22 of a spectacle frame with various further spectacle frame elements 24, inter alia with the frame front, the temples and connection elements.

If these spectacle frame elements 24 are already marked in the CAD model, it is possible to directly select the spectacle frame element 24 for which the parametric equivalent model should be determined. If no markings of individual spectacle frame elements 24 are available, or should this not be desired, it is possible to determine the parametric equivalent model for the entire spectacle frame.

The method does not require the availability of the parametric model from the frame manufacturer itself—a set of entities 30 is sufficient.

Entities 30 of the CAD model 22 are preferably available as a mesh 26. FIG. 2 shows the mesh 26 of a spectacle frame element 24. The surface of the mesh 26 consists of triangles which are defined on the basis of surface points 28 in the form of points on the surface of the spectacle frame element 24. The entities 30 may be present stored in a database 42, for example as meshes 26.

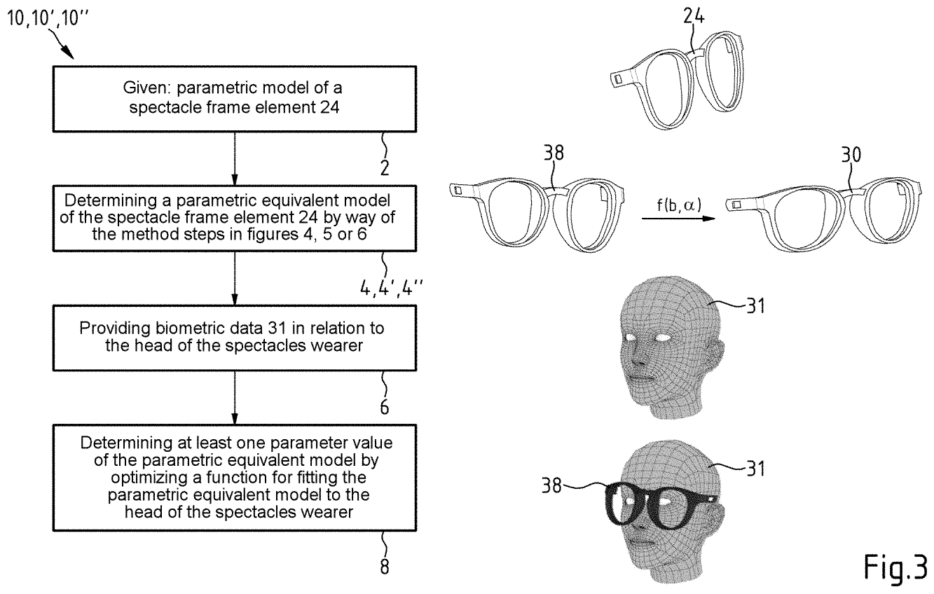

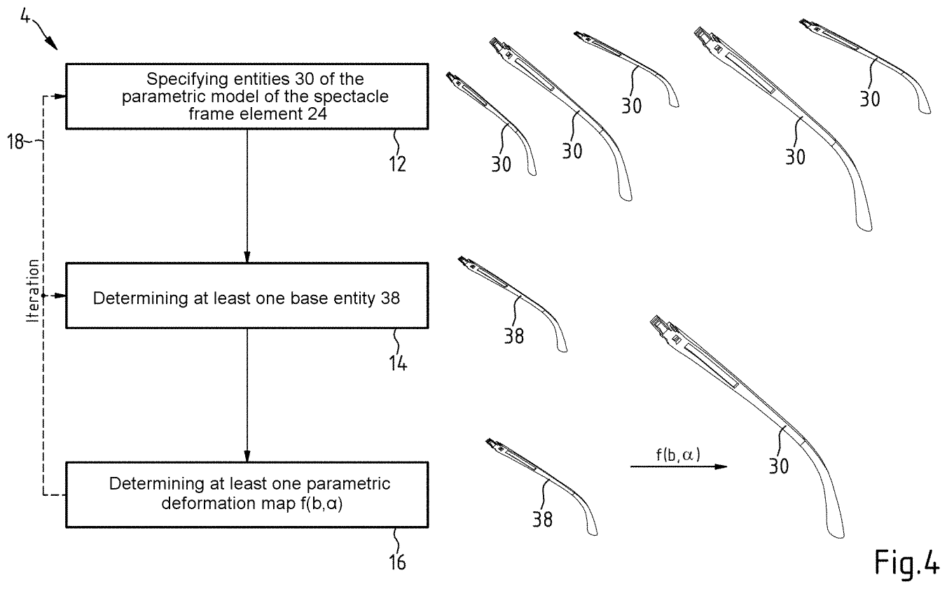

FIG. 3 shows method steps of a method 10, 10′, 10″ for individualizing a spectacle frame element by fitting a parametric model of a spectacle frame element to the head of a spectacles wearer. A parametric model of a spectacle frame element 24 is given in a first method step 2. For this parametric model, a parametric equivalent model of the spectacle frame element 24, the parametric equivalent model having at least one parameter, is determined for the given parametric model of the spectacle frame element 24 in a further method step 4, 4′, 4.″ In this case, the parametric equivalent model can be determined in three different ways, the method steps of which are depicted in FIGS. 4, 5 and 6. Biometric data 31 in relation to the head of the spectacles wearer are provided, e.g., determined, in a further method step 6. Finally, in a last method step 8, at least one parameter of the parametric equivalent model is determined by optimizing a function for fitting the parametric equivalent model to the head of the spectacles wearer.

FIG. 4 shows method steps of a method 4 for determining a parametric equivalent model of a spectacle frame element 24, the parametric equivalent model having at least one parameter, for a given parametric model of the spectacle frame element 24.

The spectacle frame element 24 shown in FIG. 4 is a temple. It is available as a parametric model in the form of a CAD model 22. However, the method 4 may also be applied to the parametric model of the entire spectacle frame.

In a first method step 12 of the method 4, entities 30 of the parametric model of the spectacle frame element 24 in the form of the temple are specified. From these specified entities, at least one base entity 38 is determined in a second step 14 and at least one parametric deformation map f(b, α) is determined in a third step 16. The at least one parametric deformation map maps a base entity b on an entity 30 of the parametric equivalent model on the basis of parameters in the form of a parameter vector α. Various entities 30 of the parametric equivalent model can be generated by inserting different parameter values for α; by way of example, the length and/or width of the temples can be varied as a result, so that the spectacle frame element 24 can be fitted to the head of the spectacles wearer.

The steps of the method 4 for generating the parametric equivalent model of the spectacle frame element 24 can be repeated in a plurality of iterations 18.

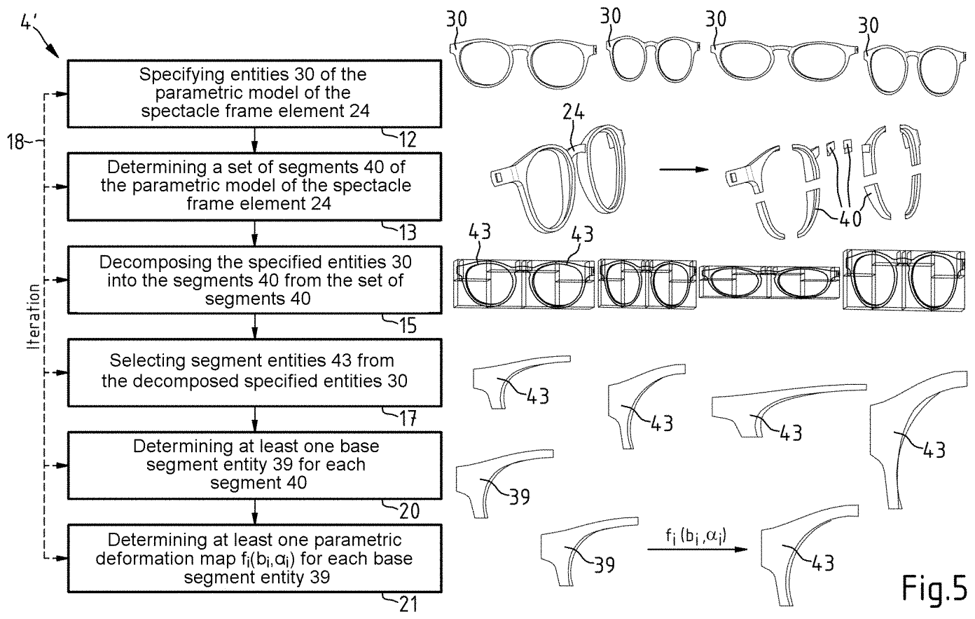

FIG. 5 shows method steps of an alternative method 4 for determining a parametric equivalent model of a spectacle frame element 24, the parametric equivalent model having at least one parameter, for a given parametric model of the spectacle frame element 24.

The spectacle frame element 24 shown in FIG. 5 is a frame front. It is available as a parametric model in the form of a CAD model 22.

In a first method step 12 of the method 4′, a plurality of entities 30 of the parametric model of the spectacle frame element 24 in the form of the frame front are specified. A set of segments 40 of the parametric model of the spectacle frame element 24 is determined in a second step 13. The specified entities 30 of the parametric model are decomposed into the segments 40 from the set of segments 40 in a further step 15. A set of segment entities 43 is selected from the decomposed specified entities in a next step 17. Thus, for each segment 40 from the set of segments 40, the respective segment 40 is selected from the decomposed specified entities 30 and the selected segments 40 are combined to form a set of specified segment entities 43, for example as shown for the top left part of the frame front in FIG. 5. A base segment entity 39 is determined for each segment 40 in a further method step 20. Thus, like in the above-described method 10, a base entity 38, the base segment entity 39, is determined from the specified segment entities. Additionally, a parametric deformation map fᵢ(bᵢ, αᵢ) is determined for each segment i for each base segment entity bᵢ in a further method step 21, the deformation map mapping the base segment entity bᵢ on further segment entities 43 of the segment i of the parametric equivalent model of the spectacle frame element 24 on the basis of the parameters αᵢ.

In this case, the specified entities 30 can be generated by varying the parameter values for the parameters of the CAD model 22.

In this case, it is advantageous if the specified entities 30 are available in a single coordinate system 32, as shown in FIG. 7. Furthermore, it is advantageous if the specified entities 30 are positioned and oriented in the coordinate system 32 in such a way that the centroid 36 of the respective entity 30 corresponds with the center of the coordinate system 32 and/or a plane of symmetry 34 of the respective entity 30 contains an axis of the coordinate system 32.

Moreover, the specified entities 30 may be pre-processed in a pre-processing step 44 in order to correct errors, for example topological defects such as holes or an irregular triangulation, for example an irregular density or size of the surface triangles, and/or in order to improve the visual impression of the entities 30 for the spectacles wearer. To this end, use can be made of a Poisson surface reconstruction algorithm, for example as described in the article “Poisson Surface Reconstruction,” Michael Kazhdan, Matthew Bolitho and Hugues Hoppe, Proceedings of the fourth Eurographics symposium on Geometry processing, 2006, the entirety of which is referred to herewith and the disclosure of which is included in the description of this disclosure.

The steps of the method 4′ for generating the parametric equivalent model of the spectacle frame element 24 can be repeated in a plurality of iterations 18.

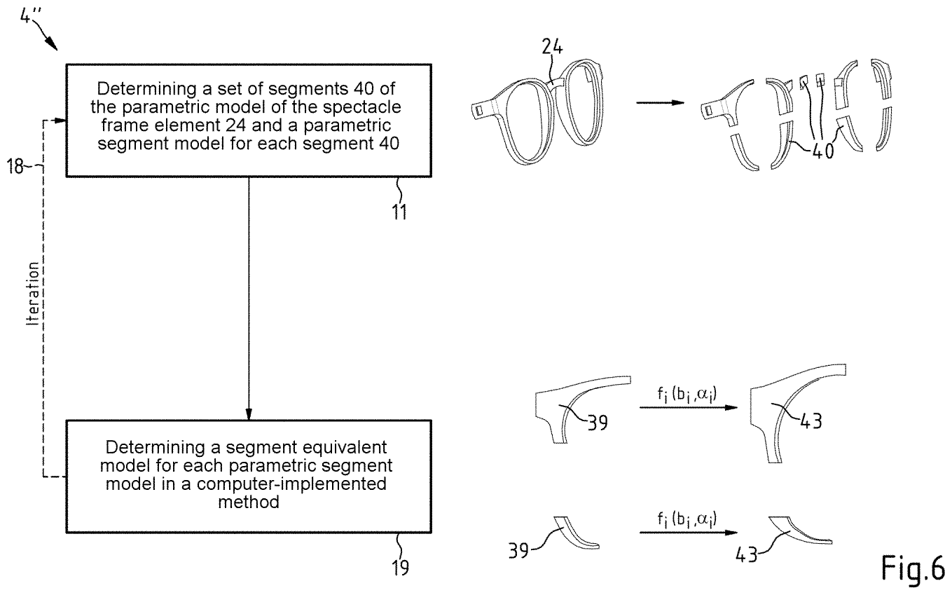

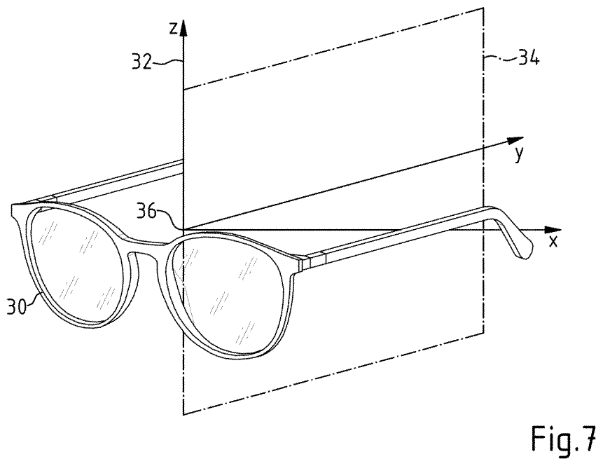

FIG. 6 shows method steps of an alternative method 4″ for determining a parametric equivalent model of a spectacle frame element 24, the parametric equivalent model having at least one parameter, for a given parametric model of the spectacle frame element 24.

The spectacle frame element 24 shown in FIG. 6 is a frame front. It is available as a parametric model in the form of a CAD model 22.

A set of segments 40 of the parametric model of the spectacle frame element 24 is determined in a first method step 12 of the method 4.″ Moreover, a parametric segment model is determined for each segment 40 on the basis of the parametric model. To this end, the parametric model can already be available in the form of individual segments, for example in a CAD file which contains a plurality of parts of a spectacle frame. Then, in a further step 19, a parametric segment equivalent model is determined for each parametric segment model by means of a method that was explained above on the basis of FIG. 4. The parametric equivalent model of the spectacle frame element 24 then contains the set of segments and the parameters of the individual segment equivalent models.

When determining the elements of the parametric equivalent model, it is advantageous in each case to optimize a criterion from the group comprising weighted sum, average, maximum and quantile of the distribution of the deviations between surfaces of the specified entities 30 of the parametric model and surfaces of all those entities 30 of the parametric equivalent model of the at least one spectacle frame element 24 which are generable on the basis of specific parameter values.

It is also advantageous if the parametric equivalent model is provided in a data format that differs from that of the parametric model. This is because this allows the parametric equivalent model to be used independently of the program and the data format in which the parametric model is available.

A set of segments 40 of the parametric model of the spectacle frame element 24 is determined in the second step 13 of the method 10′. This measure is targeted at reproducing the virtual manner of production of the parametric model from the frame manufacturer to the best possible extent.

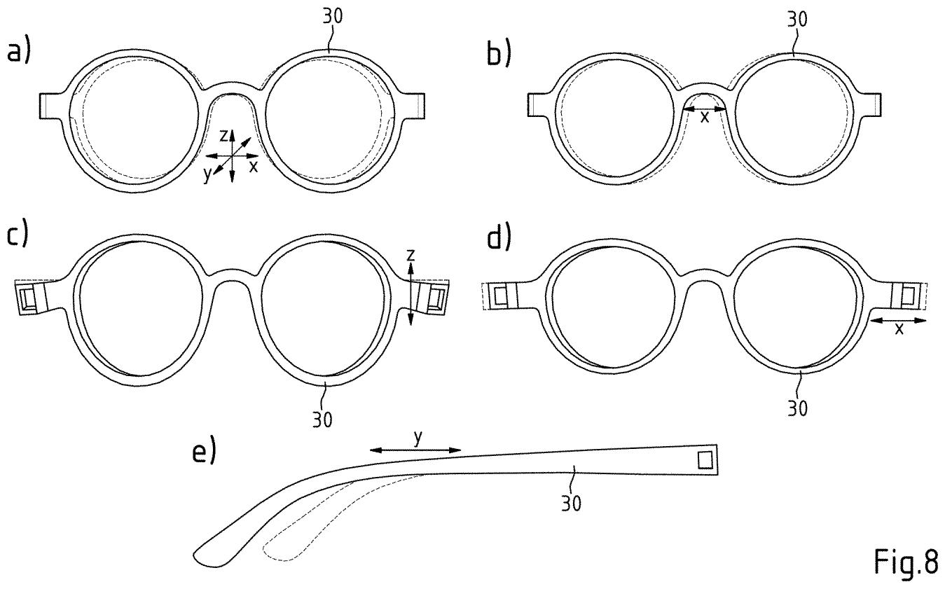

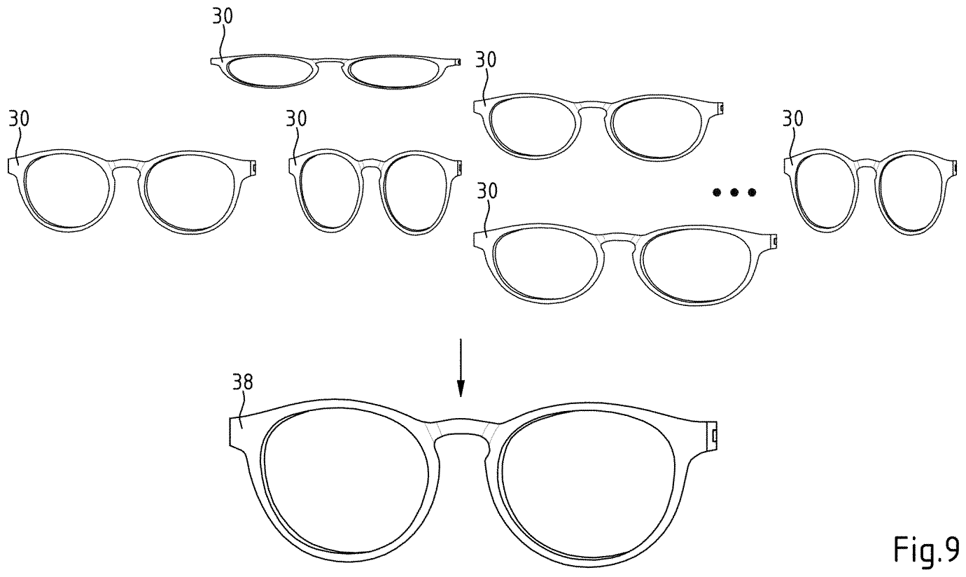

To determine the set of segments 40, it is possible to examine the effects of the various parameters of the CAD model 22 created by the frame manufacturer, for example frame size, temple length, bridge width, inclination angle and opening angle, on the geometry of the parametric model of the spectacle frame element 24 on the basis of the specified entities 30 of the parametric model of the spectacle frame element 24, as shown in FIG. 8. By way of example, the entities 30 can then be analyzed on the basis of the movement of the surface points 28 of the mesh 26 over various entities 30. By way of example, all surface points 28 that follow the same movement or all surface points 28 that do not move can be combined to form one segment 40.

As shown in FIG. 8A, the size of the frame scales the mesh 26 in all spatial directions. The bridge width in FIG. 8B scales the frame along the horizontal. The inclination angle in FIG. 8C moves the regions of the frame front at which the temples are mounted in the vertical direction, while the opening angle in FIG. 8D moves these regions in the horizontal direction. The temple length in FIG. 8E scales the length of the temples. For the frame front, the set of segments 40 determined thus may contain twelve elements, for example.

For the segments 40 from the set of segments 40 of the parametric equivalent model of the at least one spectacle frame element 24, it is possible to determine additional features for fitting the latter to the head of the spectacles wearer, for example ear support points for the temples, support curves of the ends of the temples, 3-D lens planes as an approximation for the lenses to be fitted into the spectacle frame, 3-D boxes for approximating the rims of the frame front, nose pads and/or nose support points for the frame front. These additional data may require manual interaction by the user, for example by selecting points or straight lines in the data displayed on a screen.

In step 15 of the method 10′, the specified entities 30 of the frame front are decomposed into segments 40 from the set of segments 40. The entities 30 can be segmented manually by an input by a user by way of the user interface or segmented automatically by means of an algorithm, as described on the basis of FIGS. 18 to 21.

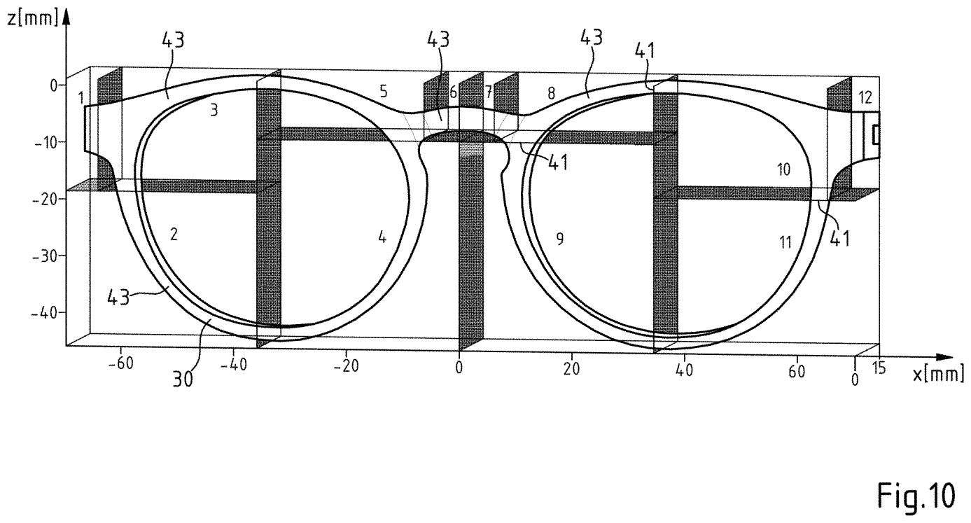

By way of example, the frame front is decomposed into the twelve segments shown in FIG. 10, the segments being labeled by numbers 1 to 12. The plotted planes each indicate the segment boundaries 41. These planes can be determined for example on the basis of an algorithm for detecting points of inflection 74, as described further below.

If the specified entities 30 are available as a mesh 26, it is advantageous if they are partitioned into disjoint segments 40 from the set of segments 40, in such a way that each segment entity 43 consists of a set of surface points 28 that is contiguous in relation to the triangulation of the mesh 26. In this case, the triangulation of the mesh 26 is maintained even after the decomposition of the specified entities 30 into segments 40.

In the second step 14 of the method 10, at least one base entity 38 is provided on the basis of the specified entities 30 of the parametric model of the spectacle frame element 24, as shown in FIG. 9. In particular, an entity 30 generated on the basis of the mean value or median of the value range or of the expected value of the probability distribution of the respective parameter is suitable here.

Alternatively, one of the specified entities 30 may also be selected as a base entity 38. In this case, the at least one base entity 38 can be chosen in such a way that further entities 30, for example the remaining specified entities 30, are reproducible with the smallest possible error by an application of the parametric deformation maps.

The at least one base entity 38 can also be selected on the basis of inputs of a user by way of the user interface or automatically by way of an algorithm. In this case, the algorithm can assess quality criteria, for example the deviation of the entities 30 reproduced on the basis of the parametric equivalent model from the specified entities 30.

The at least one base segment entity 39 can be determined in the same way from the specified entities 30 that have been decomposed into segments 40, the base segment entities 39.

In the last step 16 of the method 10, at least one parametric deformation map is determined for the at least one base entity 38 for the purposes of mapping the latter on further entities 30 of the parametric model of the spectacle frame element 24. In this case, the at least one parametric deformation map is defined in the form of a map f(b, α) with parameters α to be determined, which alter the base entity b.

By way of example, affine maps which describe a rotation, a translation and a scaling of the segments 40 can be chosen as deformation maps.

It is advantageous if the at least one parametric deformation map of the parametric equivalent model originates from the group comprising affine maps, polynomials, polynomial surfaces, Bézier curves, splines or NURBS.

In particular, it is advantageous if the segments 40 from the set of segments 40 of the parametric equivalent model are labeled static, movable or deformable.

It is particularly advantageous if the parametric deformation maps of the segments 40 labeled as static are linear maps, if the parametric deformation maps of the segments 40 labeled as movable are affine maps and if the parametric deformation maps of the segments 40 labeled as deformable are approximated on the basis of polynomials, polynomial surfaces, Bézier curves, splines or NURBS.

Segments 40 labeled as movable or deformable which do not follow a uniform movement may be connection surfaces between spectacle frame elements 24 and/or segments 40. These comprise contact curves in the respective contact region with the adjacent segment 40. It may be advantageous for these if additional connection conditions in the form of points and normal vectors at a few points of the contact curve are defined.

At least one base segment entity 39 and at least one parametric deformation map are determined for each segment 40 from the set of segments 40, in such a way that the at least one parametric deformation map maps the base segment entity 39 on further segment entities 43 with as little deviation as possible.

It is advantageous if an algorithm which minimizes the deviations of entities 30 of the parametric model from all generable entities 30 of the parametric equivalent model is used for determining the elements of the parametric equivalent model of the spectacle frame element 24, in particular the set of the segments 40, the at least one base entity 38 and/or the parametric deformation maps.

Machine learning methods can be used to determine the elements of the parametric equivalent model, in particular the at least one base entity 38 and the at least one parametric deformation map. This likewise applies to the determination of the at least one base segment entity 39 and the at least one parametric deformation map for the method 10′.

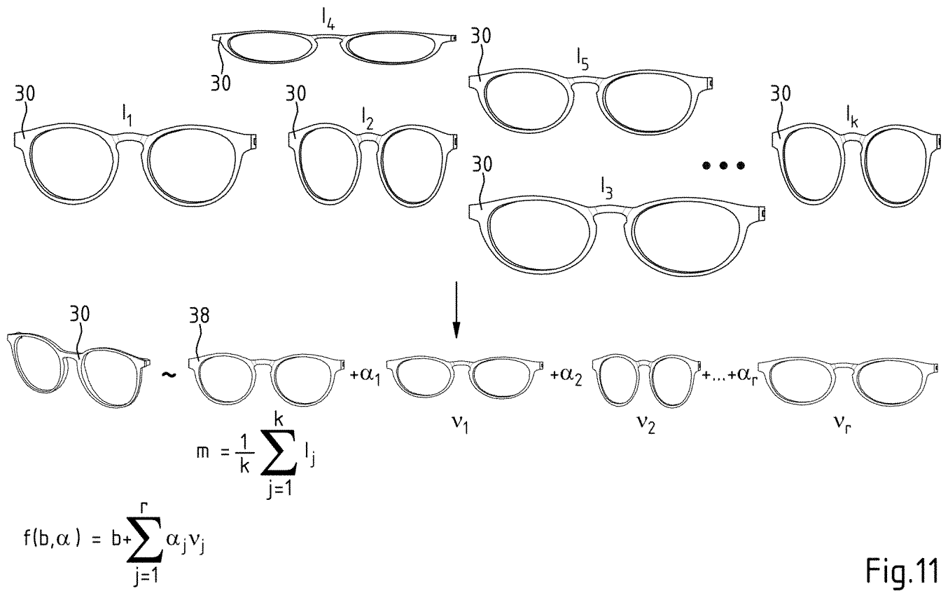

Preferably, principal component analysis can be used here, as depicted in FIG. 11. The mean value of the specified entities 30 then forms the base entity b. The parametric deformation map is determined on the basis of the eigenvectors vᵢ of the covariance matrix of the entities 30 following the subtraction of the mean value. To achieve a lower complexity of the parametric equivalent model, it is possible to this end to choose only the n eigenvectors for the n largest eigenvalues.

f(b,α)=b+Σᵢ₌₁ⁿαᵢvᵢ.

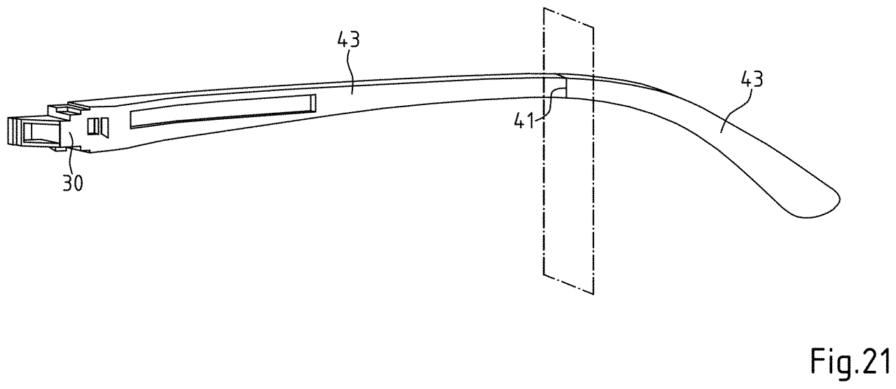

If a specific entity 30 of a CAD model 22 of a spectacle frame element 24 is available, the latter can be represented as follows on the basis of the parametric equivalent model of the at least one spectacle frame element 24 for this CAD model 22 of the spectacle frame element 24. Firstly, the entity 30 is decomposed into the segments 40 from the set of segments 40 of the parametric equivalent model of the at least one spectacle frame element 24. Then, a base entity 38 of the parametric equivalent model of the spectacle frame element 24 is chosen. Then, the specific deformation map can be calculated for each of the segments 40, the deformation map mapping the respective segment 40 of the base entity 38 to the corresponding segment 40 of the specific entity 30, for example as described further below on the basis of FIGS. 18 and 21. Consequently, the entity 30 can be represented approximately on the basis of the parametric equivalent model of the spectacle frame element 24 merely by specifying the selected base entity 38 and the parameter values for the parametric deformation maps for each of the segments 40 of the selected base entity 38.

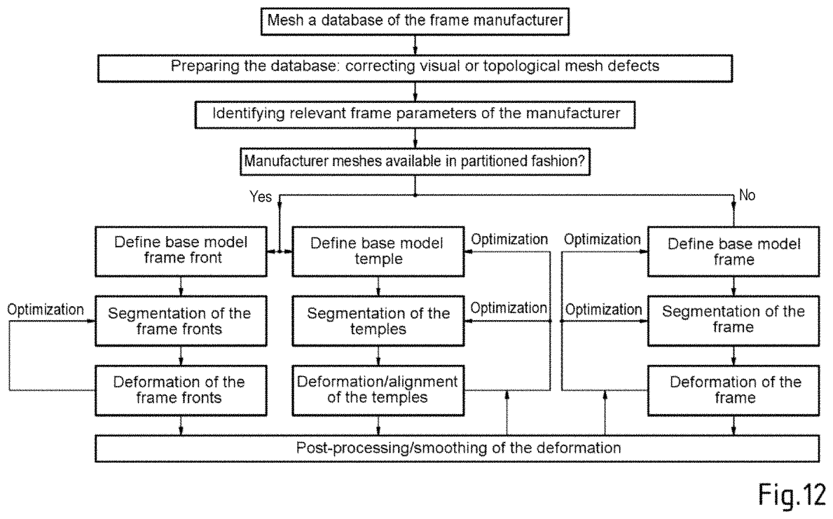

FIG. 12 shows how a parametric equivalent model of a spectacle frame element 24 is determined for specified entities 30 which are based on a common parametric model. In this case, the specified entities 30 can be stored in the form of meshes 26 in a database 42 of the frame manufacturer.

The specified entities can be pre-processed in a pre-processing step 44 for the purposes of repairing visual or topological defects.

As described on the basis of FIG. 8, a suitable set of segments 40 is determined for each spectacle frame element 24 in a next step by way of identifying relevant frame parameters of the manufacturer. In this case, the parametric model of the spectacle frame element may already be available in partitioned form, that is to say subdivided into segments. In this case, the method 4″ depicted in FIG. 6 can be used to generate a parametric equivalent model by virtue of determining a parametric segment equivalent model for each segment.

If there is no partitioning of the parametric model of the spectacle frame element 24 available, the method 4′ depicted in FIG. 5 can be used to generate a parametric equivalent model. To this end, at least one base entity 38 of the parametric equivalent model of the spectacle frame element 24 is determined in a step 14 by selecting an entity 30 from the collection of entities 30, the specified entities. The base entity 38 is decomposed into the set of segments 40 in the subsequent step 16. Thereafter, the specified entities 30 are also decomposed into the segments 40 from the set of segments 40. Thereafter, the parametric deformation maps are selected in such a way that the reconstruction error is as small as possible on the specified entities 30. The steps for determining the base entity, segmenting the base entity and determining the parametric deformation maps are iterated until the required quality criteria in the form of maximum deviations of the surface points 28 of the entities 30 of the collection of entities 30 from the surface points 28 of the respective entities 30 represented on the basis of the parametric equivalent model are met.

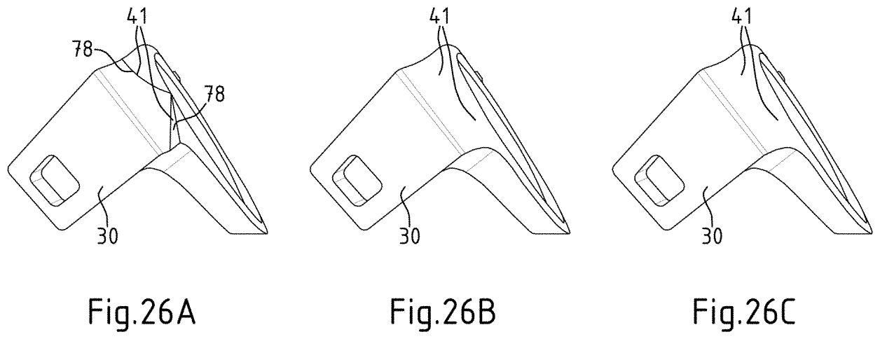

Since a dedicated deformation map is determined independently of the other segments 40 for each segment 40 of the at least one base entity 38 of the spectacle frame element 24, there may be discontinuities 78 at the segment boundaries 41. These can be prevented by a smoothing method which is applied in a post-processing step 46 on the generated meshes 26 of the entities 30, for example a Delta-Mush method as described below on the basis of FIG. 26A, FIG. 26B and FIG. 26C. An additional method step for determining a post-processing method, in particular a smoothing method, for the entities 30 generated on the basis of the parametric equivalent model is therefore advantageous.

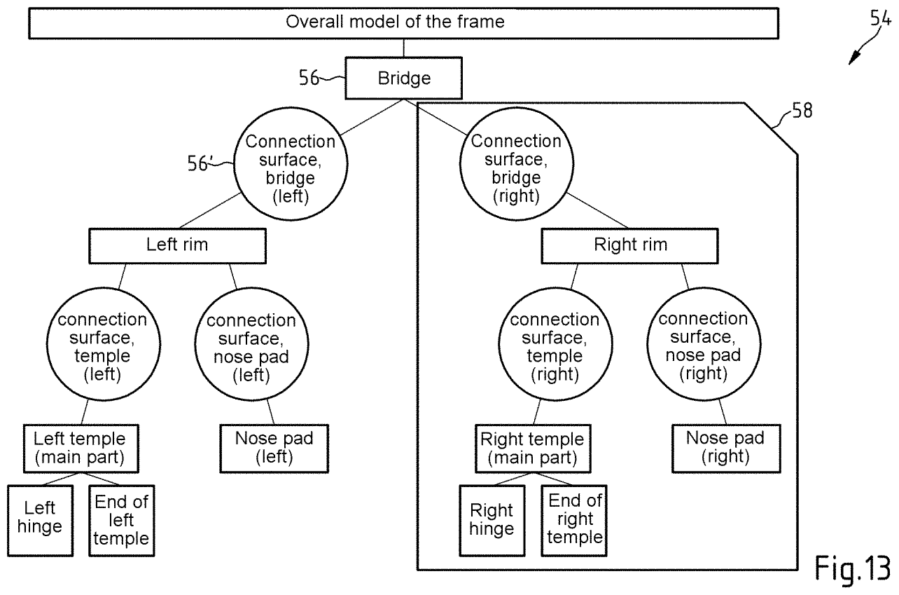

FIG. 13 shows an arrangement of the segments 40 from the set of segments 40 of a parametric equivalent model of a spectacle frame element 24, in this case of the entire spectacle frame. The segments 40 are arranged in a hierarchical tree structure 54 according to their spatial relationship. Interconnected nodes 56, 56′ indicate a spatial adjacency of the segments 40, that is to say these segments 40 have a common cut edge or cut surface. In this case, each segment 40 in the tree structure 54 is positioned and oriented relative to its parent node in a coordinate system 32.

The right subtree 58 of the “bridge” node describes the right part of the parametric model of the spectacle frame up to the bridge, the left subtree 58 describes the left part up to the bridge. The two subtrees 58 of the bridge node are symmetric since the two halves of the parametric model of the spectacle frame are also symmetric.

If a plurality of spectacle frame elements 24 are present, these can also be arranged hierarchically in a tree structure 54, for example as shown in FIG. 13.

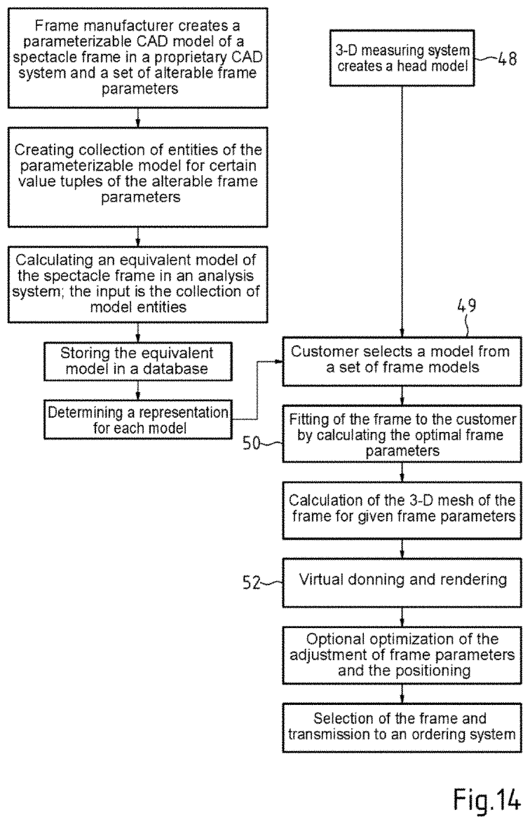

FIG. 14 depicts a computer-implemented method for individualizing a spectacle frame element 24 by fitting a parametric model of a spectacle frame element 24 to the head of a spectacles wearer on the basis of an above-described method for determining a parametric equivalent model of the spectacle frame element 24, the parametric equivalent model having at least one parameter. In this case, a representation of the head in a coordinate system 32 is determined in a computer unit. Further, a parameter value for the at least one parameter of the parametric equivalent model of the spectacle frame element 24 is determined such that the entity 30 of the parametric equivalent model of the spectacle frame element 24 generated on the basis of this at least one parameter value is fitted to the head.

To this end, the frame manufacturer creates a CAD model 22 of the spectacle frame element 24 with alterable parameters. To determine a parametric equivalent model of the spectacle frame element 24 for this model, a set of specified entities 30 of the CAD model is created for various parameter sets. The parametric equivalent model of the spectacle frame element 24 is calculated from the specified entities 30 on the basis of an above-described method. This parametric equivalent model of the spectacle frame element 24 can be stored in a database 42. A respective parametric equivalent model can then be stored in the database 42 for different CAD models 22 of different spectacle frame elements 24.

By way of example, this database 42 with parametric equivalent models of spectacle frame elements 24 can be used as follows in a system for individualizing and adapting spectacle frame elements 24:

In a first step 48, a representation of the head of the spectacles wearer is created by means of a 3-D measurement system on the basis of a head model in a coordinate system. A representation for a specific parameter set is generated for each parametric equivalent model in the database 42. This representation can also be stored together therewith in the database 42 in order to save computation time.

The spectacles wearer can select a spectacle frame element 24 from the representations of the parametric equivalent models of the various spectacle frame elements 24 in a further step 49. On the basis of the parametric equivalent model, this spectacle frame element 24 can be fitted in a step 50 to the previously created head model by means of algorithms as are described, for example, in EP 3 425 447 A1 or EP 3 425 446 A1, the entirety of which is referred to herewith and the disclosure of which is included in the description of this disclosure.

To this end, a base entity 38 is selected together with a decomposition of the latter into segments 40 of the parametric equivalent model of the spectacle frame element 24. This is transformed into the coordinate system 32 of the head model. Finally, the parameters of the parametric deformation maps are optimized for each of the segments 40 of the base entity 38, in such a way that the spectacle frame element 24 is fitted to the head model.

It should be observed that, in principle, in step 50, the parametric equivalent model can also be used to optimally fit the spectacle frame element 24 to the previously created head model manually on the basis of user inputs via a user interface. The parameter values determined in the process are stored for the spectacles wearer.

Then, a mesh 26 of the spectacle frame element 24 is calculated for the selected parametric equivalent model of the spectacle frame element 24 and the optimized parameter values of this model. This can be indicated in a step 52 in the worn position on the head model of the spectacles wearer.

Optionally, parameter values of the parametric equivalent model of the spectacle frame element 24 or the position of the rendered spectacle frame element 24 can be fitted to the head model.

The selected spectacle frame element 24 can then be transmitted to an ordering system.

If the various spectacle frame elements 24 are stored together with the parametric equivalent models thereof in the ordering system, all that needs to be transferred for an order are the calculated parameter values of the parametric equivalent model, that is to say optionally the index of the selected base entity 38 if a plurality thereof are contained in the model, and the parameter values of the deformation maps, saving transmission time and even being possible in the case of a low-bandwidth Internet connection.

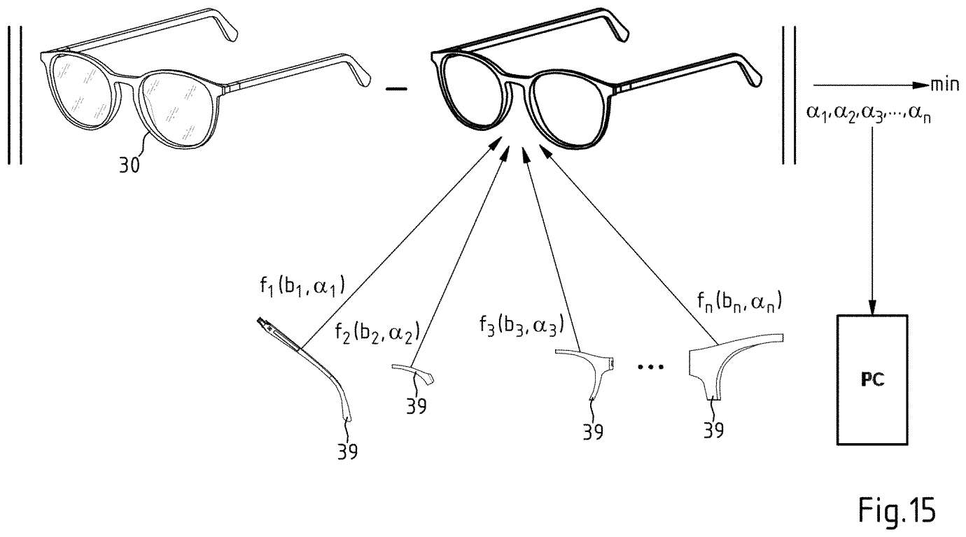

A computer-implemented method for representing and/or compressing a given entity 30 of a parametric model of a spectacle frame element 24 on the basis of a parametric equivalent model of the spectacle frame element 24 determined in an above-described method, the parametric equivalent model having at least one parameter, in a computer unit is described on the basis of FIG. 15. In this case, a parameter value is determined for each parameter of the parametric equivalent model in a first step, by virtue of a criterion being optimized from the group comprising weighted sum, average, maximum and quantile of the distribution of the deviations between surfaces of the given entity 30 of the parametric model and surfaces of the entity 30 of the parametric equivalent model generated on the basis of this at least one parameter value. The determined at least one parameter value is stored in a memory of the computer unit. FIG. 15 shows that, for this measure, the deviation of the given entity 30 from the entities 30 generable on the basis of the parametric equivalent model is minimized by determining optimal parameter values. These parameter values are stored in a memory of a computer unit. The entities 30 generable on the basis of the parametric equivalent model are in this case generated by the decomposition of the parametric model into the set of segments 40 and by the application of the parametric deformation maps f₁(b₁, α₁), . . . fₙ(bₙ, αₙ) to the various base segment entities 39 for the n segments.

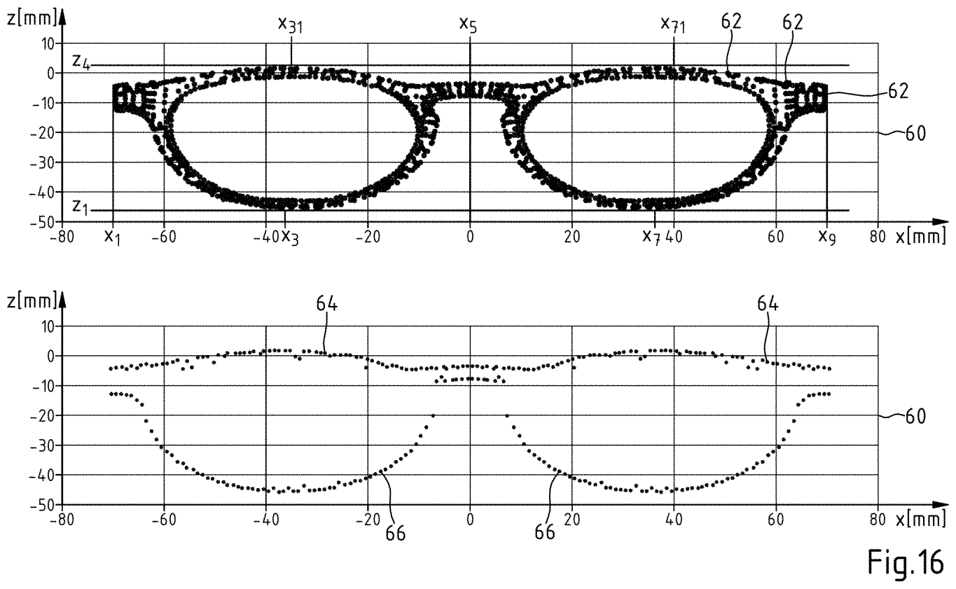

FIGS. 16 to 22 describe how the decomposition of an entity 30 of a parametric model or a parametric equivalent model of a spectacle frame element 24 into the segments 40 from the set of segments 40 can be determined automatically on the basis of an algorithm.

The algorithm comprises the following steps: projecting the surface points 28 of the mesh 26 of the entity 30 on a plane 60, determining signals 72 at the protection points 62 associated with rims 68, 70 of the entity 30, and determining the points of inflection 74 of these signals 72 and the mean values of the partial signals 76, 76′. The decomposition can then be described using a parameter set of n elements Z⊂ [symbol] ⁿ.

In the present example of the frame front, the set of segments 40 consists of twelve segments 40. So that the segmentation method is applicable to various entities 30 of the same parametric model, the entities 30 are available in an aligned fashion in a coordinate system 32, as described on the basis of FIG. 7.

The surface points 28 of the mesh 26 of the entity 30 to be decomposed are projected along a spatial axis on a plane 60, as shown in FIG. 16. The projection points 62 in the form of the projected points can be sorted along one axis, the abscissa in this case.

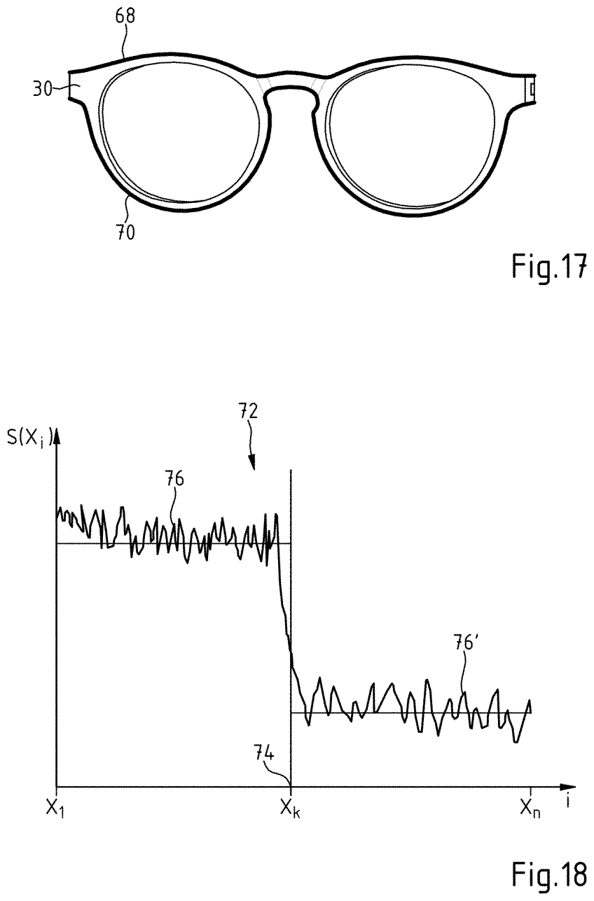

Two sets are selected from the projection points 62: the first set 64 contains projection points 62 for surface points 28 of the upper rim 68 of the entity 30 of the CAD model of the frame front shown in FIG. 17. The second set 66 contains projection points 62 for surface points 28 of the lower rim 70 of the entity 30 of the CAD model of the frame front in FIG. 17.

By way of example, the abscissa can be sensed at regular intervals, for example of 1 mm, to this end.

To obtain the first set 64 of projection points 62, a set of projection points 62 with a similar abscissa value can be determined for each sensed value on the abscissa, and the projection point 62 with the greatest value on the ordinate axis can be selected therefrom.

To obtain the second set 66 of projection points 62, a set of projection points 62 with a similar abscissa value can be determined for each sensed value on the abscissa, and the projection point 62 with the smallest value on the ordinate axis can be selected therefrom.

Then, the entity 30 can be decomposed automatically by means of an algorithm into segments 40 from the set of segments 40 on the basis of the first set 64 and the second set 66 of projection points 62 for an entity 30 of the parametric model of a spectacle frame element 24.

The upper rim 68 in the plane 60 represented by the first set 64 of projection points 62 as a contour and the lower rim 70 in the plane 60 represented by the second set 66 of projection points 62 as a contour can be considered to be signals 72, for the decomposition of which it is possible to use signal processing algorithms, for example an algorithm for detecting points of inflection 74 as described in the article “Using penalized contrasts for the change-point problem, Marc Lavielle, Signal Processing, 2005, volume 85, pp. 1801-1810,” the entirety of which is referred to herewith and the disclosure of which is included in the description of this disclosure.

If a signal 72 is available like the signal shown in FIG. 18, the points of inflection 74 of this signal 72 can be determined automatically on the basis of this algorithm. Let S: [symbol] → [symbol] be the continuous signal 72, which adopts the values S(X₁), . . . S(Xₙ) (vertical axis) at the sampling points X₁, . . . Xₙ (horizontal axis). It is possible to calculate a point of inflection 74 in the section of the signal 72 containing X₁, . . . Xₙ, by virtue of minimizing the target function J: [symbol] → [symbol] ₀⁺ comprising the sum of the variances of the first partial signal 76 containing X₁, . . . Xₖ₋₁ and of the second partial signal 76′ containing Xₖ, . . . Xₙ on the basis of the following optimization problem:

$${min}_{k} J ( k ) = ( k - 1 ) \cdot Var ( S ( {X}_{1} ) , … , S ( {X}_{k - 1} ) ) + ( N - k + 1 ) \cdot Var ( S ( {X}_{k} ) , … , S ( {X}_{N} ) ) \qquad ( 1 )$$

The optimization problem (1) can be modified in such a way that any desired number of points of inflection 74 can be detected in a signal 72.

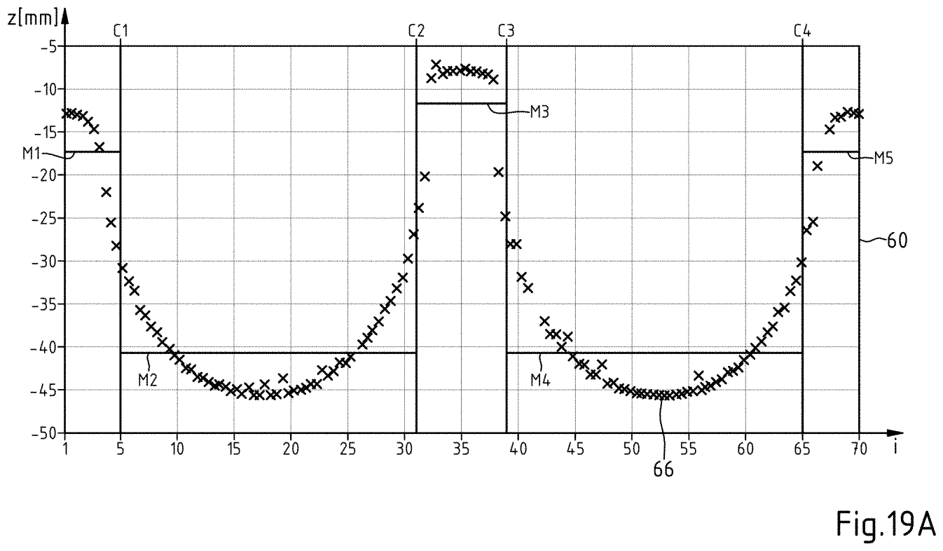

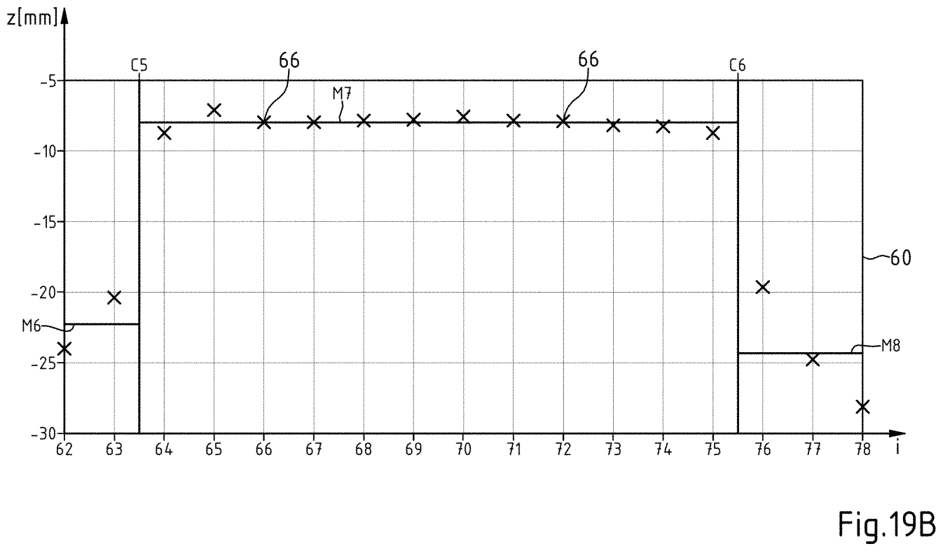

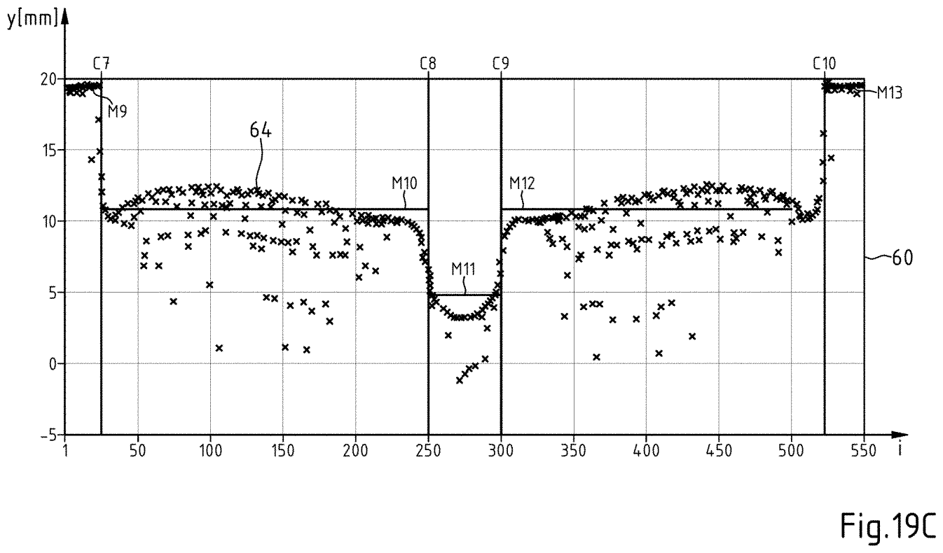

FIGS. 19A, B and C show the calculation of the points of inflection 74 in the signals 72 from the first set 64 and the second set 66 of projection points 62. The vertical lines in each case show the coordinates C₁, . . . , C₁₀ of the detected points of inflection 74 in the signal 72, the horizontal lines show the mean values M₁, . . . , M₁₃ of the partial signals 76, 76′.

In FIG. 19A, the optimization problem (1) is solved for four points of inflection 74 on the basis of the lower rim 70 described by the second set 66 of projection points 62, and so the sum of the variances of the five partial signals 76, 76′ is minimized. The horizontal axis shows the index i of the projection point 62 from the second set 66 of projection points 62, which are associated with surface points 28 of the lower rim 70, in the xz-plane 60. The vertical axis shows the z-coordinate of the projection points 62.

FIG. 19B is a section of the signal 72 in FIG. 19A, specifically the part of the second set 66 of projection points 62 in the interval [C₂, C₃], which are located on the lower rim 70 of the projected surface points 28 of the bridge. The horizontal axis shows the index i of the projection point 62 from the second set 66 of projection points 62, which are associated with surface points 28 of the lower rim 70, in the xz-plane 60. The vertical axis shows the z-coordinate of the projection points 62. For this signal section, two points of inflection 74 are detected again in a subsequent step.

FIG. 19C shows the determination of four points of inflection 74 for the first set 64 of projection points 62 of the upper rim 68.

The decomposition of an entity 30 of the parametric model of the frame front can for example be described by the following parameter set

Z=(x₁,x₂,x₃,x₃₂,x₄,x₅,x₆,x₇,x₇₁,x₈,x₉,Z₁,Z₂,Z₂₁,Z₃,Z₄) (2)

with 16 parameter values:
x₁ minimum abscissa coordinate of all projection points 62
x₉: maximum abscissa coordinate of all projection points 62
z₁: minimum ordinate coordinate of all projection points 62
z₄: maximum ordinate coordinate of all projection points 62

$${x}_{5 :} = \frac{{x}_{1} + {x}_{9}}{2}$$

x₃: abscissa coordinate for the minimum ordinate coordinate in [x₁,x₅]
x₃₂: abscissa coordinate for the maximum ordinate coordinate in [x₁,x₅]
x₇: abscissa coordinate for the minimum ordinate coordinate in [x₅,x₉]
x₇₁: abscissa coordinate for the maximum ordinate coordinate in [x₅,x₉]
z₂: M₁
z₂₁: M₅
x₄: C₅
x₆: C₆
z₃: M₇
x₂: C₇
x₈: C₁₀.

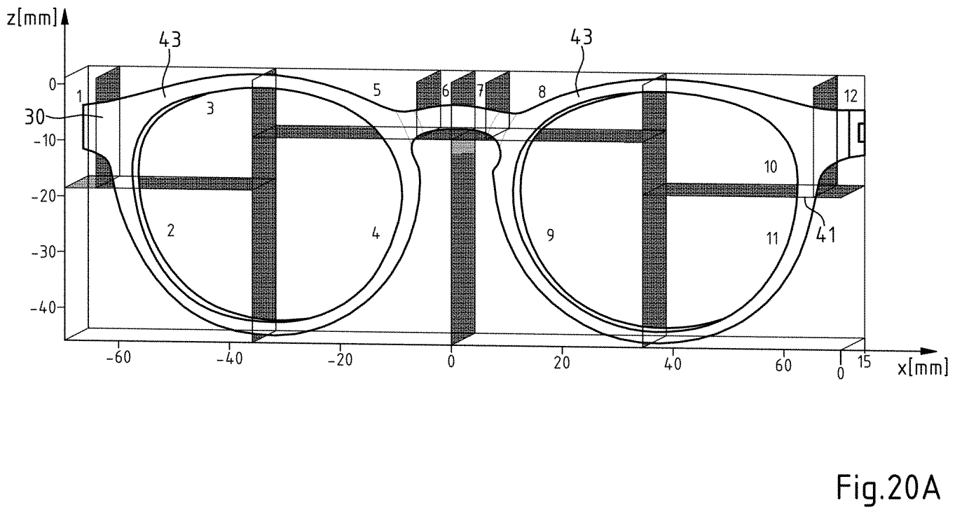

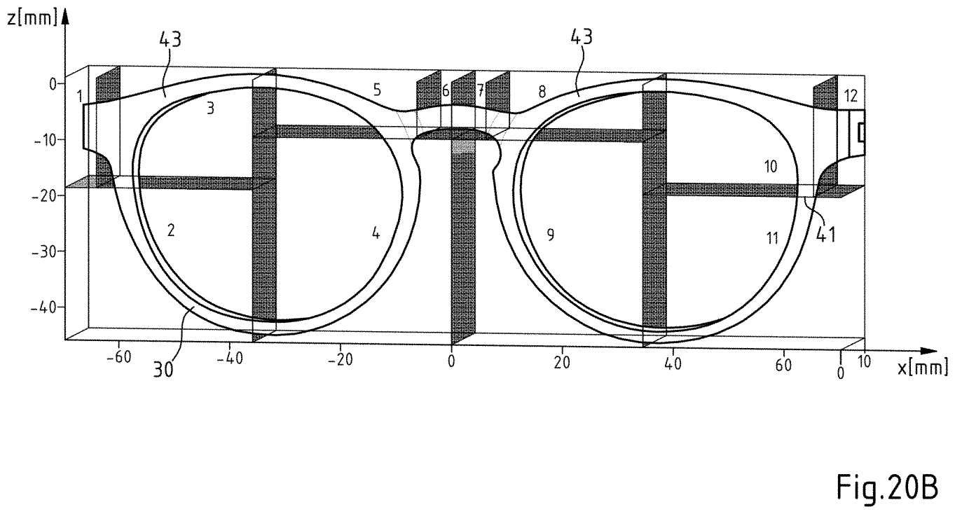

FIG. 20A shows the decomposition of an entity 30 of a parametric equivalent model of a frame front into twelve segments 40 determined on the basis of the above-described algorithm for detecting points of inflection 74. FIG. 20B shows the decomposition of a further entity 30 of the parametric equivalent model of a frame front into twelve segments 40 calculated on the basis of the same algorithm. In this case, all surface points 28 located within a region labeled by a numeral are part of the same segment 40 with segment boundaries 41. Segments 40 of the two entities 30 in FIG. 20A and FIG. 20B that have been labeled by the same numeral correspond to one another.

FIG. 21 shows the decomposition of an entity 30 of a CAD model of a temple into two segments 40.

Since the same decomposition algorithm is applied to all entities 30 of the parametric model of the at least one spectacle frame element 24 or of the parametric equivalent model of the at least one spectacle frame element 24, each segment 40 of the one entity 30 can be directly assigned the corresponding segment 40 in the further entities 30. On the basis of these correspondences, it is possible to determine the parametric deformation maps for mapping the base segment entities 39 to further corresponding segment entities 43.

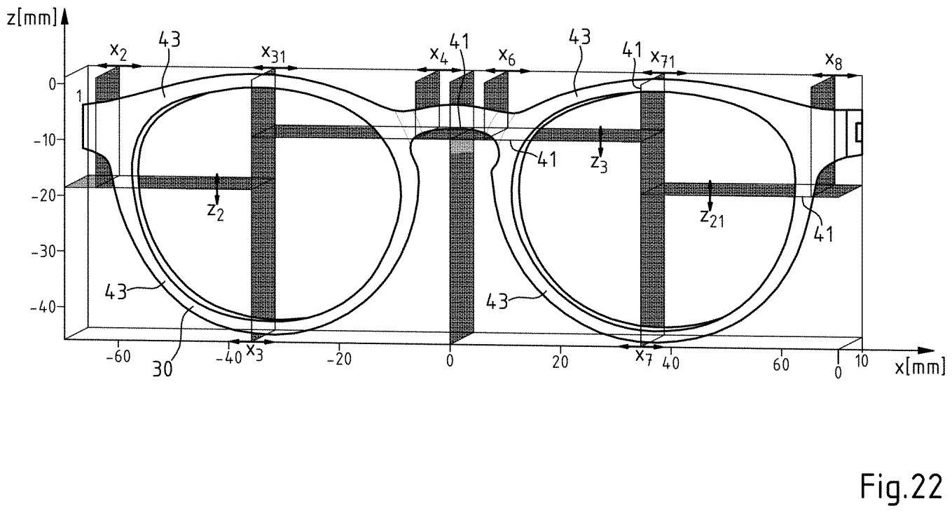

To improve the accuracy of the parametric deformation maps, it is possible to optimize the segmentation of the entities 30 by varying the parameter values Z in (2), as shown in FIG. 22. This can improve the ability to map different segment entities 43 on the same segment 40 on one another.

As an alternative to the detection of points of inflection 74 in signals 72 from rims 68, 70 for the purposes of determining the parameter set Z in (2) for decomposing entities 30 into segments 40 from the set of segments 40, it is possible to use mesh segmentation methods, multivariate fitting methods, skeletonization methods and/or machine learning methods.

In order to be able to represent an entity 30 of a parametric model of a spectacle frame element 24 on the basis of a parametric equivalent model of the spectacle frame element 24, the decomposition of the entity 30 into the segments 40 from the set of segments 40 must be followed by a determination of the parameter values of the associated parametric deformation maps for each of these segments 40.

To this end, use can be made of algorithms for aligning 3-D objects which minimize distances between point clouds, for example an iterative closest point (ICP) algorithm as described in the article “S. Rusinkiewicz and M. Levoy, Efficient variants of the ICP algorithm, Proceedings of the Third International Conference on 3-D Digital Imaging and Modeling, pp. 145-182, 2001,” the entirety of which is referred to herewith and the disclosure of which is included in the description of this disclosure.

An assumption can be made that the triangulation of the surface points 28 in the form of the triangular mesh, in particular the topology and the linking of the triangular structure, does not change when the parameter values of the parametric deformation maps are altered. The algorithms for determining the parameter values of the parametric deformation maps, for example the ICP algorithms, can then operate directly on the surface points 28 of the mesh 26. This saves computation time.

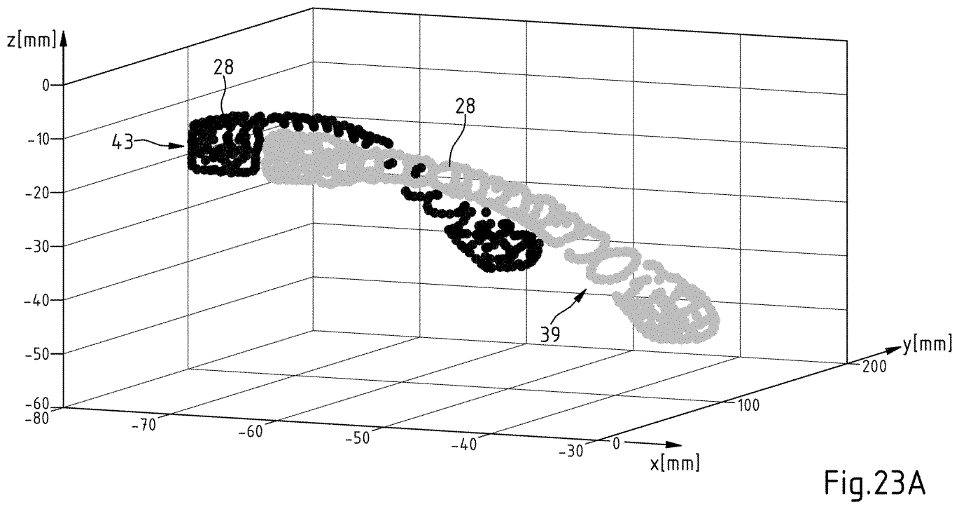

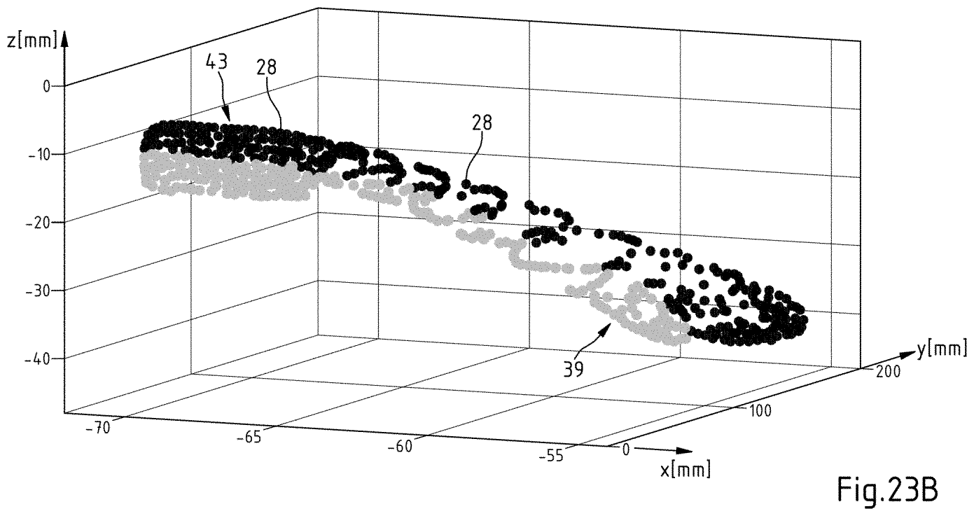

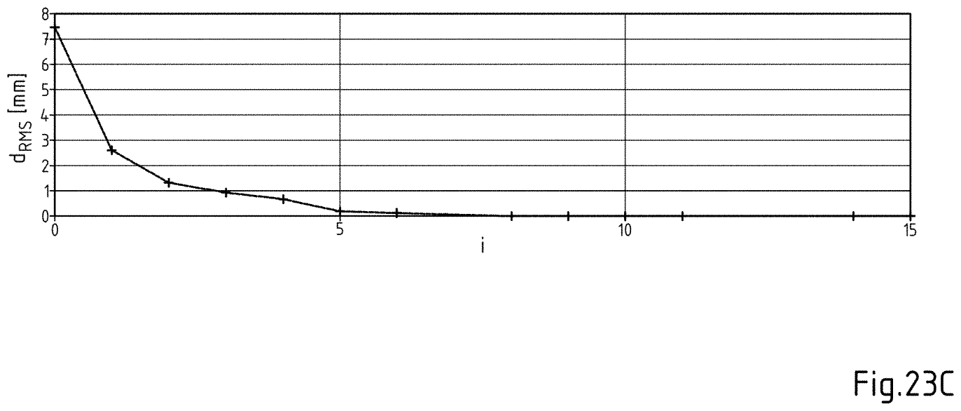

FIG. 23A shows the deformation of a base segment entity 39 of a segment 40 of a parametric model of a temple on the basis of the ICP algorithm, such that the distance of the surface points 28 of the mesh 26 of this base segment entity 39 from the surface points 28 of the mesh 26 of the corresponding segment 40 in a further entity 30 of the parametric model of the temple is as small as possible.

FIG. 23A shows the surface points 28 of the mesh 26 of the base segment entity 39 and of the further segment entity 43 in a coordinate system 32 before the application of the ICP algorithm, FIG. 23B shows the two segments 40 after 18 iterations of the algorithm.

FIG. 23C shows the curve of the root mean square error of the shortest distances of the surface points 28 of the base segment entity 39 and the further segment entity 43 from one another.

For some spectacle frame elements 24, for example for the temples, the parametric deformation maps for the segments 40 can be chosen particularly easily, for example merely as a combination of a rotation matrix and a translation vector. Then, the parameter values can be determined on the basis of the ICP algorithm.

In this case, maps of the form

f: [symbol] ³→ [symbol] ³, f(x)=R·x+t, R∈SO(3),t∈R³

can be chosen as parametric deformation maps, where SO(3) denotes the special orthogonal group of all rotations about the origin in three-dimensional Euclidean space.

In this case, the following optimization problem is solved iteratively, the optimization problem minimizing the sum, weighted with weights wᵢ, of the distances of the surface points pᵢ of the mesh 26 of a base segment entity 39 from the surface points qᵢ, closest to pᵢ, of the mesh 26 of the corresponding segment 40 of the further entity 30:

$$( R , t ) = {min}_{R ∈ SO ( 3 ) , t ∈ {R}^{3}} \{ {\sum }_{i = 1}^{N} {w}_{i} ‖ ( R * {p}_{i} + t ) - {q}_{i} ‖ \} . \qquad ( 3 ) .$$

The weights can be chosen as wᵢ=1. Alternatively, other weights are also applicable. By way of example, the weight wᵢ for the points pᵢ and qᵢ can be determined on the basis of the angle between the surface normals present at this point:

wᵢ=pᵢ·qᵢ.

The surface normals for a point can be estimated from the closest neighbors of this point in the point cloud. This type of weighting is described, for example, in the aforementioned article regarding ICP algorithms.

Alternatively, other ICP variants are also applicable, for example as described in the article “A Method for Registration of 3-D Shapes,” Paul J. Besl and Neil D. McKay, IEEE Transactions on Pattern Analysis and Machine Intelligence, volume 14, edition 2, 1992, the entirety of which is referred to herewith and the disclosure of which is included in the description of this disclosure.

Advantageous for the speed of the method is the use of the point-to-plane ICP algorithm, for example as described in the article “Kok-Lim Low, Linear Least-Squares Optimization for Point-to-Plane ICP Surface Registration,” Department of Computer Science University of North Carolina at Chapel Hill, February 2004, the entirety of which is referred to herewith and the disclosure of which is included in the description of this disclosure. In this case, it is not the distance between the surface points of the entities that is minimized but the distance between the surface points of one entity and the tangential planes at the closest surface points of the other entity.

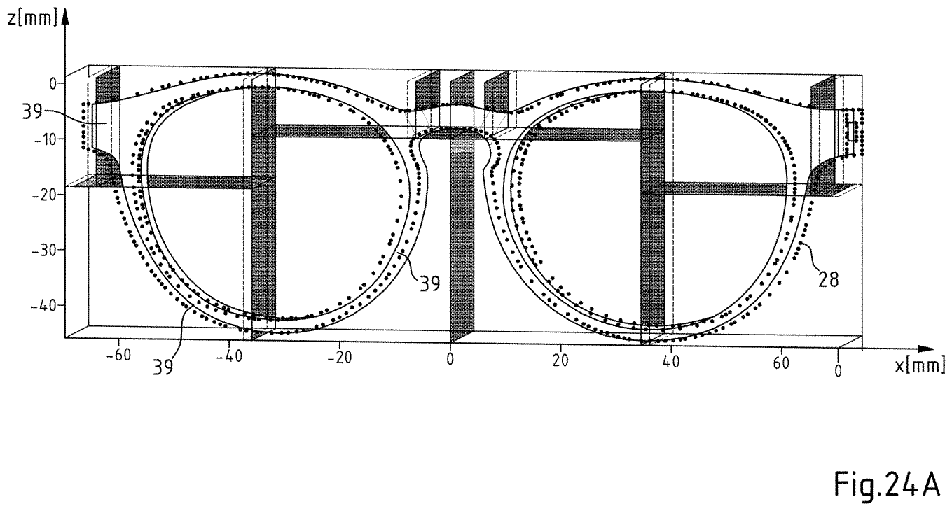

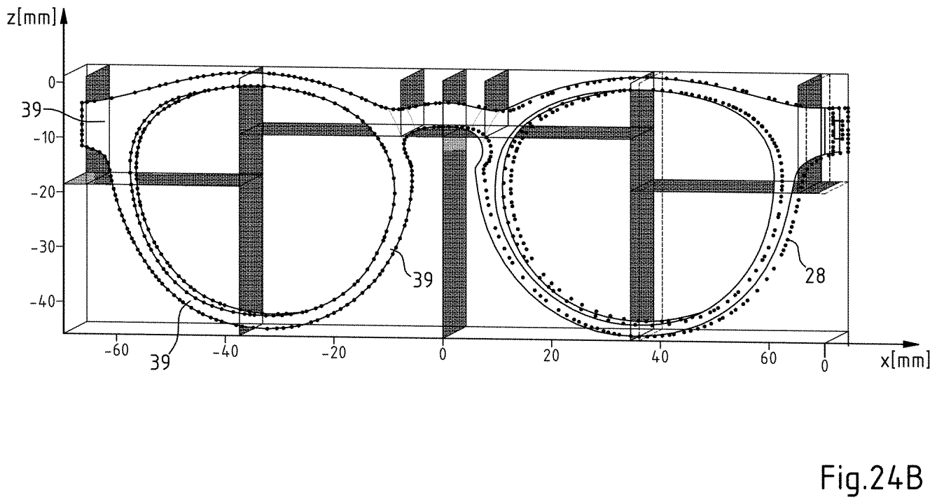

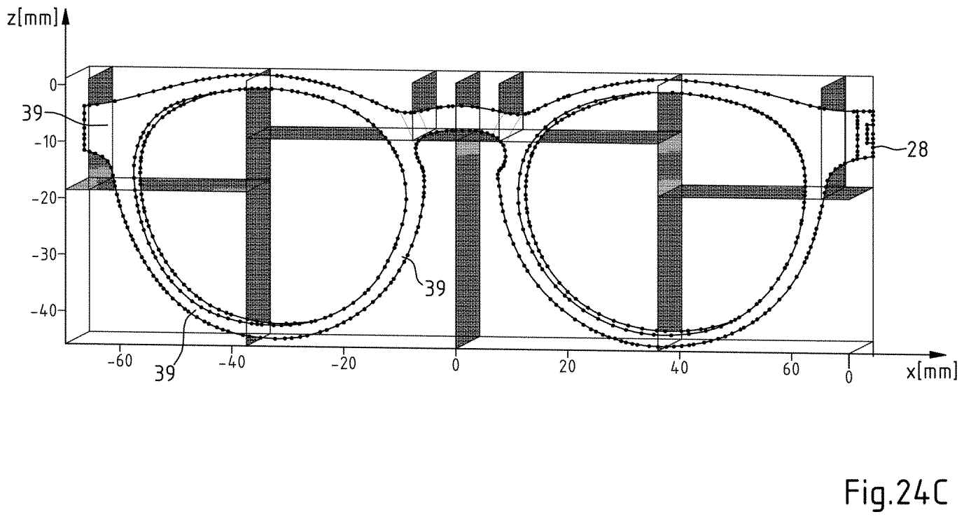

FIG. 24A shows an example for the determination of the parameter values of the parametric deformation maps for the different base segment entities 39 of a parametric model of the frame front. In this case, the deviation of the surface points 28 of the mesh 26 of the base segment entities 39 from the closest surface points 28 of the mesh 26 of the segments 40 of the further entity 30 is minimized on the basis of the optimization problem (3).

FIG. 24A shows the base segment entities 39 and the surface points 28 of the further entity 30 before the application of the ICP algorithm. FIG. 24B shows the minimized deviation for the segments 40 enumerated 1 to 6, FIG. 24C shows this for all segments 40 following the determination of the parameter values of the deformation maps.

As an alternative to the ICP algorithms, it is also possible to use other deformation methods for determining the parameter values of the parametric deformation maps, in particular mesh editing methods. In this context, a surface is deformed on the basis of control points by solving a sparsely populated matrix problem. Examples of mesh editing methods include Laplacian surface editing, for example described in the article “Laplacian Surface Editing, O Sorkine, D. Cohen-Or, Eurographics Symposium on Geometry Processing, 2004,” or Poisson surface editing, described in the article “Mesh Editing with Poisson-Based Gradient Field Manipulation, Yizhou Yu et al., ACM SIGGRAPH 2004.”

The integration of symmetry assumptions in respect of individual segments 40 of the parametric model of the at least one spectacle frame element 24, for example of the left and of the right temple, into the parametric equivalent model of the at least one spectacle frame element 24 is advantageous.

In the case of a rather small variation of the parametric model of a spectacle frame element 24, the complexity of the parametric equivalent model can be reduced by using a larger set of base entities 38 instead of parametric deformation maps.

The determined parametric equivalent model for the parametric model of the frame front may contain the following elements with parameters:
the number of segments 40 of the parametric model of the frame front;
the meshes 26 of the at least one base segment entity 39 of the frame front;
the parameter set Z in (2), containing the 16 parameters that describe the boundaries of the twelve segments 40;
12 rotation matrices and 12 translation vectors with parameters to be determined, which describe the parametric deformation maps for each segment 40 of the base segment entities 39;
parameters of a post-processing step 46.

The parameter set Z in (2) that describes the decomposition of the parametric model is optional in this case since it has to be recalculated at all times on the basis of the decomposition algorithm and consequently need not be stored as well as a parameter of the parametric equivalent model. This saves transmission time and memory space. However, the additional storage saves computation time.

For a specific entity 30 of the parametric equivalent model of the frame front, it is sufficient to store the following parameter values:
the index of the respectively selected base segment entity 39 for each segment 40 of the parametric equivalent model if a plurality of base segment entities 39 are available for one segment 40;
the parameter values of the parametric deformation maps.

These parameter values can be transmitted to video centration equipment. There, the specific entity 30 can be restored merely on the basis of the respective index of the base segment entity 39 and of the parameter values of the parametric deformation maps, and on the basis of the parametric equivalent model, stored there, of the at least one spectacle frame element 24. Consequently, there is no need to transfer the entire mesh 26 of the specific entity 30 or of the parametric equivalent model of the at least one spectacle frame element 24 to the video centration equipment and store it there. The use of the parametric equivalent model consequently saves memory space and transmission time.

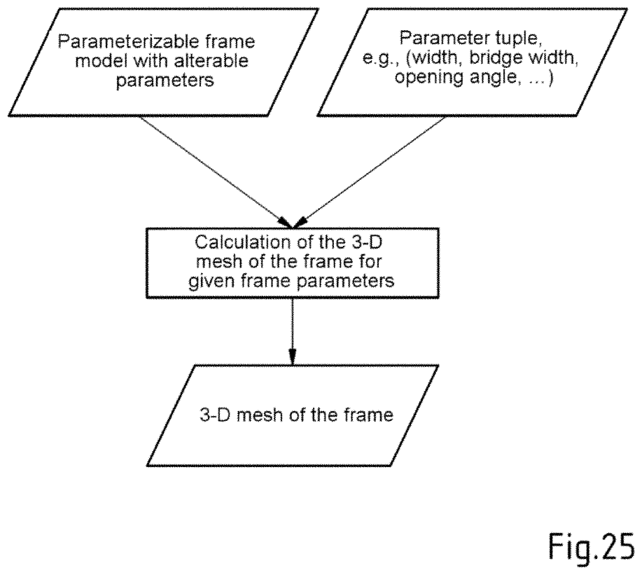

On the basis of the parametric equivalent model, it is possible by selecting parameter values to generate a mesh 26 of a spectacle frame element 24, as shown in FIG. 25.

To avoid discontinuities 78 at segment boundaries 41 that may arise on account of the calculation of the parameter values for the parametric deformation maps being carried out independently for each segment 40, it is possible to use smoothing methods such as, e.g., the Delta Mush method, which is described in the article “Delta Mush: Smoothing Deformations while Preserving Detail, Joe Mancewicz, Matt L. Derksen, Hans Rijpkema, Cyrus A. Wilson, Proceedings of the 4th Symposium on Digital Production, 2014,” the entirety of which is referred to herewith and the disclosure of which is included in the description of this disclosure.

The Delta Mush method is advantageous over other smoothing methods in that there is only a small change in the mesh 26 on account of smoothing, and so calculations that require particularly high accuracy, for example a virtual centration, are possible even with the parametric equivalent model of the at least one spectacle frame element 24.

FIG. 26A, FIG. 26B, and FIG. 26C explain the application of the Delta Mush method to the segment boundaries 41 using an entity 30 of a parametric equivalent model of a connection point. FIG. 26A shows an entity 30 of the parametric equivalent model of the connection point with discontinuities 78 at the segment boundaries 41. FIG. 26B shows the segments 40 without discontinuities 78 following smoothing by the Delta Mush method. For comparison purposes, FIG. 26C shows the original entity 30 of the parametric model of the connection point.

A computer program product according to the disclosure contains a computer program with program code for carrying out the aforementioned method steps when the computer program is loaded into a computer unit and/or executed on a computer unit.

An apparatus for individualizing and fitting a parametric model of a spectacle frame element to the head of a spectacles wearer contains a computer unit, loaded in which there is a computer-implemented method for fitting the parametric model of the spectacle frame element to a representation of the head in a coordinate system.

An apparatus for representing and/or compressing a given entity of a parametric model of a spectacle frame element contains a computer unit having a memory, loaded in which there is a computer-implemented method for representing and/or compressing the given entity in the memory of the computer unit.

A system according to the disclosure having a device for producing a spectacle frame element individualized in an above-described method for individualizing a spectacle frame element or for grinding spectacle lenses into a spectacle frame element individualized in an above-described method for individualizing a spectacle frame element uses the at least one determined parameter value of the parametric equivalent model.

In summary, the following, in particular, should be noted: The disclosure relates to a method 10, 10′ for determining a parametric equivalent model of a spectacle frame element 24 for a parametric model of the spectacle frame element 24 for the purposes of fitting this parametric equivalent model to the head of a spectacles wearer. In this context, at least one base entity 38 is provided by creating at least one entity 30 of the parametric model of the spectacle frame element 24 in the form of a realization of the parametric model of the at least one spectacle frame element 24 on the basis of a set of specific parameter values. At least one parametric deformation map is determined for the at least one base entity 38, the at least one parametric deformation map mapping the at least one base entity 38 on entities 30 of the parametric model, the parametric equivalent model being determined at least from the at least one base entity 38 and from the at least one parametric deformation map. Alternatively, a set of segments 40 can be determined for the parametric model of the spectacle frame element 24. At least one base segment entity 39 and at least one parametric deformation map are determined for each segment 40. The at least one parametric deformation map then maps at least one base segment entity 39 on further segment entities 43 of the parametric model, the parametric equivalent model being determined at least from the set of segments 40 and from the at least one base segment entity 39 and the at least one parametric deformation map for each segment 40 from the set of segments 40.

Exemplary embodiments are described in the following clauses:

Clause 1. A computer-implemented method (10) for determining a parametric equivalent model for a parametric model of a spectacle frame element (24), the parametric equivalent model having at least one parameter, wherein

a plurality of entities (30) of the parametric model are specified in the form of realizations of the parametric model by means of specific parameter values,

at least one base entity (38) and

at least one parametric deformation map for the at least one base entity (38) is determined from the specified entities (30), the at least one parametric deformation map mapping the at least one base entity (38) on entities (30) of the parametric model, and the parametric equivalent model being determined at least from the at least one base entity (38) and from the at least one parametric deformation map.

Clause 2. A computer-implemented method (10) for determining a parametric equivalent model for a parametric model of a spectacle frame element (24), the parametric equivalent model having at least one parameter, wherein

a plurality of entities (30) of the parametric model are specified in the form of realizations of the parametric model by means of specific parameter values,

a set of segments (40) is determined for the parametric model of the spectacle frame element (24),

the specified entities (30) are decomposed into the segments (40) from the set of segments (40),

segment entities (43) are generated for each segment (40) from the set of segments (40) by virtue of entities (30) of this segment (40) being selected from the decomposed specified entities (30),

at least one base segment entity (39) and

at least one parametric deformation map for the at least one base segment entity (39) is determined from these segment entities (43),

the at least one parametric deformation map mapping the at least one base segment entity (39) on segment entities (43) of the parametric model,

and the parametric equivalent model being determined at least from the set of segments (40) and from the at least one base segment entity (39) and the at least one parametric deformation map for each segment (40) from the set of segments (40).

Clause 3. A computer-implemented method (10) for determining a parametric equivalent model for a parametric model of a spectacle frame element (24), the parametric equivalent model having at least one parameter, wherein

a plurality of entities (30) of the parametric model are specified in the form of realizations of the parametric model by means of specific parameter values,

a set of segments (40) is determined for the parametric model of the spectacle frame element (24),

the specified entities (30) are decomposed into the segments (40) from the set of segments (40),

segment entities (43) are generated for each segment (40) from the set of segments (40) by virtue of entities (30) of this segment (40) being selected from the decomposed specified entities (30),

a parametric equivalent model having at least one parameter is determined as a segment equivalent model for each segment (40) in a computer-implemented method according to clause 1, the segment entities (43) associated with each segment being used in this context as specified entities,

and the parametric equivalent model being determined at least from the set of segments (40) and from the parametric segment equivalent models having at least one parameter.

Clause 4. The method according to clause 2 or 3, characterized in that the segments (40) from the set of segments (40) are labeled as static, movable or deformable.

Clause 5. The method according to clause 4, characterized in that the parametric deformation maps are linear maps for the segments (40) labeled as static and/or in that the parametric deformation maps of the segments (40) labeled as movable are affine maps and/or in that the parametric deformation maps of the segments (40) labeled as deformable are approximated on the basis of Bézier curves, splines or NURBS.

Clause 6. The method according to any one of clauses 2 to 5, characterized in that a method for recognizing points of inflection (74) in signals (72) and/or a mesh segmentation method and/or a multivariate fitting method and/or a skeletonization method and/or a machine learning method is applied during the decomposition of entities (30) of the parametric model of the spectacle frame element (24) into segments (40) from the set of segments (40); and/or

in that the segments (40) from the set of segments (40) are arranged hierarchically in a tree structure (54) in such a way that the nodes (56, 56′) connected in the tree structure (54) are associated with segments (40) with a common cut edge or cut surface in the parametric model;

and/or

in that each segment (40) in the tree structure (54) is positioned and oriented relative to its parent segment in a coordinate system (32)

and/or

in that entities (30) of the parametric equivalent model in the form of realizations of the parametric equivalent model are post-processed by means of specific parameter values on the basis of an algorithm for avoiding discontinuities (78) at segment boundaries (41).

Clause 7. The method according to any one of clauses 1 to 6, characterized in that additional features from the group comprising ear support points, nose support points, support curves of the ends of the temples, 3-D lens planes, 3-D boxes, nose pads are determined for the parametric equivalent model of the spectacle frame element (24);

and/or

in that the parametric deformation maps originate from the group comprising affine maps, polynomials, polynomial surfaces, Bezier curves, splines or NURBS;

and/or

in that method steps for determining the parametric equivalent model are iterated.

Clause 8. The method according to any one of clauses 1 to 7, characterized in that, for determining the parametric equivalent model, a criterion is optimized from the group comprising weighted sum, average, maximum and quantile of the distribution of the deviations between surfaces of the specified entities (30) of the parametric model and surfaces of all those entities (30) of the parametric equivalent model of the at least one spectacle frame element (24) which are generable on the basis of specific parameter values, and/or

in that the specified entities (30) of the parametric model are at least partly post-processed by means of an algorithm for rectifying errors and/or for improving the visual impression for the spectacles wearer and/or for smoothing.

Clause 9. A provision of a parametric equivalent model determined in a method according to any one of clauses 1 to 8, in a data format that differs from that of the parametric model.

Clause 10. A computer-implemented method for individualizing a spectacle frame element (24) by fitting a parametric model of a spectacle frame element (24) to the head of a spectacles wearer on the basis of a parametric equivalent model of the spectacle frame element (24), the parametric equivalent model having at least one parameter and being determined in a method according to any one of clauses 1 to 8 or provided on the basis of clause 9,

characterized by

the determination of a representation of the head in a coordinate system (32) in a computer unit; and

the determination of a parameter value for the at least one parameter of the parametric equivalent model of the spectacle frame element (24) such that the entity (30) of the parametric equivalent model of the spectacle frame element (24) generated on the basis of this at least one parameter value is fitted to the head.

Clause 11. A computer-implemented method for representing and/or compressing a given entity (30) of a parametric model of a spectacle frame element (24) in a computer unit on the basis of a parametric equivalent model of the spectacle frame element (24), the parametric equivalent model having at least one parameter and being determined in a method according to any one of clauses 1 to 8 or provided on the basis of the method according to clause 9, characterized by

the determination of a respective parameter value for the at least one parameter of the parametric equivalent model of the spectacle frame element (24) by optimizing a criterion from the group comprising weighted sum, average, maximum and quantile of the distribution of the deviations between surfaces of the given entity (30) of the parametric model and surfaces of the entity (30) of the parametric equivalent model generated on the basis of this at least one parameter value; and

the storage of the at least one determined parameter value in a memory of the computer unit.

Clause 12. A computer program having program code for carrying out all method steps which are specified in any one of clauses 1 to 11 when the computer program is loaded on a computer unit and/or executed on a computer unit.

Clause 13. An apparatus for individualizing and fitting a parametric model of a spectacle frame element (24) to the head of a spectacles wearer, comprising a computer unit containing a computer-implemented method according to clause 10 for fitting the parametric model of the spectacle frame element (24) to a representation of the head in a coordinate system (32) in the computer unit.

Clause 14. An apparatus for representing and/or compressing a given entity (30) of a parametric model of a spectacle frame element (24), comprising a computer unit having a memory, the computer unit containing a computer-implemented method according to clause 11 for representing and/or compressing the given entity in the memory of the computer unit.

Clause 15. A system having a device for producing a spectacle frame element (24) that was individualized in a method according to clause 10 or for grinding spectacle lenses into a spectacle frame element (24) that was individualized according to clause 10, using the at least one determined parameter value of the parametric equivalent model.

The foregoing description of the exemplary embodiments of the disclosure illustrates and describes the present invention. Additionally, the disclosure shows and describes only the exemplary embodiments but, as mentioned above, it is to be understood that the disclosure is capable of use in various other combinations, modifications, and environments and is capable of changes or modifications within the scope of the concept as expressed herein, commensurate with the above teachings and/or the skill or knowledge of the relevant art.

The term “comprising” (and its grammatical variations) as used herein is used in the inclusive sense of “having” or “including” and not in the exclusive sense of “consisting only of.” The terms “a” and “the” as used herein are understood to encompass the plural as well as the singular.

All publications, patents and patent applications cited in this specification are herein incorporated by reference, and for any and all purposes, as if each individual publication, patent or patent application were specifically and individually indicated to be incorporated by reference. In the case of inconsistencies, the present disclosure will prevail.

### LIST OF REFERENCE SIGNS

2 Method step: specifying a parametric model of a spectacle frame element
4, 4′, 4″ Method step: determining a parametric equivalent model of the spectacle frame element
6 Method step: providing biometric data relating to the head of the spectacles wearer
8 Method step: determining at least one parameter value of the parametric equivalent model by optimizing a function for fitting the parametric equivalent model to the head of the spectacles wearer
10, 10′, 10″ Method
12 Method step: specifying entities of the parametric model of the spectacle frame element
13 Method step: decomposing the parametric model of the spectacle frame element into a set of segments
14 Method step: determining at least one base entity
15 Method step: decomposing the specified entities into the segments from the set of segments
16 Method step: determining at least one parametric deformation map
17 Method step: selecting segment entities from the decomposed specified entities
18 Iterating the method steps for optimizing the parametric equivalent model
20 Method step: determining at least one base segment entity for each segment
21 Method step: determining at least one parametric deformation map for each base segment entity
22 CAD model
24 Spectacle frame element
26 Mesh
28 Surface points
30 Entity
31 Biometric data
32 Coordinate system
34 Plane of symmetry
36 Centroid
38 Base entity
39 Base segment entity
40 Segment
41 Segment boundary
42 Database
43 Segment entity
44 Pre-processing step
46 Post-processing step
48 Method step: generating a head model
49 Method step: selecting a base entity
50 Method step: fitting the parametric equivalent model to the head of a spectacles wearer
52 Method step: virtual donning and rendering of an entity of a parametric model
54 Tree structure
56, 56′ Nodes
58 Subtree
60 Plane
62 Projection points
64 First set of projection points
66 Second set of projection points
68 Upper rim
70 Lower rim
72 Signal
74 Point of inflection
76, 76′ Partial signal
78 Discontinuity
C₁, . . . , C₁₀ Coordinates of detected points of inflection
M₁, . . . , M₁₃ Mean values of partial signals between points of inflection
f, fᵢ Parametric deformation map
α, αᵢ Parameters of the parametric deformation maps
b Base entity
bᵢ Base segment entity

What is claimed is:

1. A computer-implemented method for individualizing a spectacle frame element by fitting a parametric model of the spectacle frame element to the head of a spectacles wearer, the method comprising:
determining a parametric equivalent model for the parametric model of the spectacle frame element, the parametric equivalent model having at least one parameter, by virtue of:
specifying a plurality of entities of the parametric model in form of realizations of the parametric model with specific parameter values;
determining at least one base entity; and
determining at least one parametric deformation map for the at least one base entity from the specified plurality of entities, the at least one parametric deformation map mapping the at least one base entity on respective entities of the parametric model, and the parametric equivalent model being determined at least from the at least one base entity and from the at least one parametric deformation map;
providing biometric data relating to the head of the spectacles wearer; and
determining at least one parameter value for the at least one parameter of the parametric equivalent model of the spectacle frame element by optimizing a function which considers at least one surface point of a determined base entity of the parametric equivalent model of the spectacle frame element and the biometric data provided in relation to the head of the spectacles wearer.

2. A computer-implemented method for individualizing a spectacle frame element by fitting a parametric model of the spectacle frame element to the head of a spectacles wearer, the method comprising:
determining a parametric equivalent model for the parametric model of the spectacle frame element, the parametric equivalent model having at least one parameter, by virtue of:
specifying a plurality of entities of the parametric model in form of realizations of the parametric model with specific parameter values;
determining a set of segments for the parametric model of the spectacle frame element, the specified entities being decomposed into segments from the set of segments;
generating segment entities for each segment from the set of segments by selecting entities of a respective segment from the decomposed specified entities;
determining at least one base segment entity;
determining at least one parametric deformation map for the at least one base segment entity from the segment entities,
the at least one parametric deformation map mapping the at least one base segment entity on segment entities of the parametric model; and
determining the parametric equivalent model at least from the set of segments and from the at least one base segment entity and the at least one parametric deformation map for each segment from the set of segments;
providing biometric data relating to the head of the spectacles wearer; and
determining at least one parameter value for the at least one parameter of the parametric equivalent model of the spectacle frame element by optimizing a function which considers at least one surface point of at least one determined base segment entity of the parametric equivalent model of the spectacle frame element and the biometric data provided in relation to the head of the spectacles wearer.

3. A computer-implemented method for individualizing a spectacle frame element by fitting a parametric model of the spectacle frame element to the head of a spectacles wearer, the method comprising:
determining a parametric equivalent model for the parametric model of the spectacle frame element, the parametric equivalent model having at least one parameter, by virtue of:
determining a set of segments for the parametric model of the spectacle frame element, the parametric segment model from the parametric model of the spectacle frame element being determined for each segment,
determining a parametric equivalent model having at least one parameter as a parametric segment equivalent model for each parametric segment model with the computer-implemented method as claimed in claim 1; and
determining the parametric equivalent model from at least the set of segments and from the parametric segment equivalent model having at least one parameter;
providing biometric data relating to the head of the spectacles wearer; and
determining at least one parameter value for the at least one parameter of the parametric equivalent model of the spectacle frame element by optimizing a function which considers at least one surface point of a determined base entity of the at least one segment equivalent model of the parametric equivalent model of the spectacle frame element and the biometric data provided in relation to the head of the spectacles wearer.

4. The method as claimed in claim 2, wherein the segments from the set of segments are labeled as static, movable, or deformable.

5. The method as claimed in claim 4, wherein the parametric deformation maps are linear maps for the segments labeled as static and/or wherein the parametric deformation maps of the segments labeled as movable are affine maps, and/or wherein the parametric deformation maps of the segments labeled as deformable are approximated based on Bézier curves, splines, or NURBS.

6. The method as claimed in claim 2, wherein a method for recognizing points of inflection in signals and/or a mesh segmentation method and/or a multivariate fitting method and/or a skeletonization method and/or a machine learning method is applied during the decomposition of the entities of the parametric model of the spectacle frame element into segments from the set of segments, and/or
wherein the segments from the set of segments are arranged hierarchically in a tree structure such that nodes connected in the tree structure are associated with segments with a common cut edge or cut surface in the parametric model, and/or
wherein each segment in a tree structure is positioned and oriented relative to its parent segment in a coordinate system, and/or
wherein entities of the parametric equivalent model in the form of realizations of the parametric equivalent model are post-processed with specific parameter values based on an algorithm for avoiding discontinuities at segment boundaries.

7. The method as claimed in claim 1, wherein additional features from the group containing ear support points, nose support points, support curves of ends of temples, 3-D lens planes, 3-D boxes, and nose pads are determined for the parametric equivalent model of the spectacle frame element, and/or
wherein the parametric deformation maps originate from the group containing affine maps, polynomials, polynomial surfaces, Bézier curves, splines, or NURBS, and/or
wherein method steps for determining the parametric equivalent model are iterated.

8. The method as claimed in claim 1, wherein, for determining the parametric equivalent model, a criterion is optimized from the group including weighted sum, average, maximum, and quantile of the distribution of the deviations between surfaces of the specified entities of the parametric model and surfaces of all those entities of the parametric equivalent model of the at least one spectacle frame element which are generable based on the specific parameter values, and/or
wherein the specified entities of the parametric model are at least partly post-processed with an algorithm for rectifying errors, for improving a visual impression for the spectacles wearer, and/or for smoothing.

9. The method as claimed in claim 1, wherein the biometric data in relation to the head of the spectacles wearer includes at least one surface point of a representation of the head of the spectacles wearer.

10. The method as claimed in claim 9, wherein the function to be optimized minimizes the distance between point clouds, with a first point cloud containing at least one surface point of a base entity of the parametric equivalent model of the spectacle frame element and a second point cloud containing at least one surface point of the representation of the head of the spectacles wearer.

11. A provision of a parametric equivalent model determined in a method as claimed in claim 1, in a data format that differs from that of the parametric model.

12. A computer-implemented method for representing and/or compressing a given entity of a parametric model of a spectacle frame element in a computer unit on the basis of a parametric equivalent model of the spectacle frame element, the parametric equivalent model having at least one parameter and being determined in a method as claimed in claim 1, the method comprising:
determining a respective parameter value for the at least one parameter of the parametric equivalent model of the spectacle frame element by optimizing a criterion from the group comprising weighted sum, average, maximum and quantile of the distribution of the deviations between surfaces of the given entity of the parametric model and surfaces of the entity of the parametric equivalent model generated based on the at least one parameter value; and
storing the at least one determined parameter value in a memory of the computer unit.

13. A computer program stored on a non-transitory storage medium and having program code for carrying out all method steps of claim 1 when the computer program is loaded on a computer unit and/or executed on a computer unit.

14. An apparatus for individualizing and fitting a parametric model of a spectacle frame element to the head of a spectacles wearer, the apparatus comprising:
a computer unit containing a computer-implemented method as claimed in claim 1 for fitting the parametric model of the spectacle frame element to the head of the spectacles wearer in the computer unit.

15. An apparatus for representing and/or compressing a given entity of a parametric model of a spectacle frame element, the apparatus comprising:
a computer unit having a memory, the computer unit containing a computer-implemented method as claimed in claim 12 for representing and/or compressing the given entity in the memory of the computer unit.

16. A system having a device for producing a spectacle frame element that was individualized with the method as claimed claim 1, utilizing the at least one determined parameter value of the parametric equivalent model.

17. A system having a device for grinding spectacle lenses into a spectacle frame element that was individualized as claimed in claim 1, utilizing the at least one determined parameter value of the parametric equivalent model.

18. The method as claimed in claim 9, wherein the biometric data in relation to the head of the spectacles wearer includes a mesh of the head of the spectacles wearer.

19. The method as claimed in claim 3, wherein the segments from the set of segments are labeled as static, movable, or deformable.

20. The method as claimed in claim 19, wherein the parametric deformation maps are linear maps for the segments labeled as static and/or wherein the parametric deformation maps of the segments labeled as movable are affine maps, and/or wherein the parametric deformation maps of the segments labeled as deformable are approximated based on Bézier curves, splines, or NURBS.
